(19) United States
(12) Patent Application Publication
(10) Pub. No.: US 2016/0260883 A1
(43) Pub. Date: Sep. 8, 2016

(54) THERMOELECTRIC CONVERSION ELEMENT AND METHOD FOR MANUFACTURING THERMOELECTRIC CONVERSION ELEMENT

(71) Applicant: FUJIFILM Corporation, Tokyo (JP)

(72) Inventors: Osamu YONEKURA, Kanagawa (JP); Naoyuki HAYASHI, Kanagawa (JP); Takeyoshi KANO, Kanagawa (JP); Toshiaki AOAI, Kanagawa (JP); Hiroki SUGIURA, Kanagawa (JP)

(73) Assignee: FUJIFILM Corporation, Tokyo (JP)

(21) Appl. No.: 15/156,938

(22) Filed: May 17, 2016

Related U.S. Application Data
(63) Continuation of application No. PCT/JP2014/082973, filed on Dec. 12, 2014.

(30) Foreign Application Priority Data
Dec. 27, 2013 (JP) 2013-271493
Aug. 27, 2014 (JP) 2014-172922

(51) Int. Cl. H01L 35/24; H01L 35/10; H01L 35/34

(52) U.S. Cl. CPC H01L 35/24; H01L 35/34; H01L 35/10

(57) ABSTRACT

Provided are a thermoelectric conversion element which has a thermoelectric conversion layer made of an organic material and is capable of generating electric power at a favorable efficiency and a method for manufacturing the thermoelectric conversion element. When the thermoelectric conversion element has a first substrate having a highly thermal conductive portion having a higher thermal conductivity than other regions in a surface direction, a thermoelectric conversion layer which is formed on the first substrate, is made of an organic material, and has a higher electrical conductivity in the surface direction than in a thickness direction, and a second substrate which is formed on the thermoelectric conversion layer and has a highly thermal conductive portion which has a higher thermal conductivity than other regions in the surface direction and in which the highly thermal conductive portion does not fully overlap the highly thermal conductive portion of the first substrate in the surface direction, the problem is solved.

### CROSS-REFERENCE TO RELATED APPLICATIONS

This application is a Continuation of PCT International Application No. PCT/JP2014/082973 filed on Dec. 12, 2014, which claims priority under 35 U.S.C. §119(a) to Japanese Patent Application No. 2013-271493 filed on Dec. 27, 2013, and Japanese Patent Application No. 2014-172922 filed on Aug. 27, 2014. Each of the above application(s) is hereby expressly incorporated by reference, in its entirety, into the present application.

### BACKGROUND OF THE INVENTION

1. Field of the Invention

The present invention relates to a thermoelectric conversion element. Specifically, the present invention relates to a thermoelectric conversion element which has a thermoelectric conversion layer made of an organic material and is capable of efficient power generation and a method for manufacturing the thermoelectric conversion element.

2. Description of the Related Art

Thermoelectric conversion materials capable of converting heat energy to electrical energy and vice versa are used in thermoelectric conversion elements such as power generation elements or Peltier elements which generate power using heat.

Thermoelectric conversion elements are capable of directly converting heat energy to electric power and, advantageously, do not require any movable portions. Therefore, thermoelectric conversion modules (power generation devices) obtained by connecting a plurality of thermoelectric conversion elements are capable of easily obtaining electric power without the need of operation costs when provided in, for example, heat-exhausting portions of incineration furnaces, a variety of facilities in plants, and the like.

Generally, thermoelectric conversion elements have a constitution in which an electrode is provide on a plate-like substrate, a thermoelectric conversion layer (power generation layer) is provided on the electrode, and a plate-like electrode is provided on the thermoelectric conversion layer (so-called uni leg-type thermoelectric conversion elements).

That is, in ordinary thermoelectric conversion elements, a thermoelectric conversion layer is sandwiched between electrodes in a thickness direction, and a temperature difference is caused in the thickness direction of the thermoelectric conversion layer, thereby converting heat energy to electrical energy.

In contrast, JP3981738B and JP2011-35205A describe thermoelectric conversion elements in which a temperature difference is caused in the surface direction of a thermoelectric conversion layer instead of the thickness direction of the thermoelectric conversion layer using a substrate having a highly thermal conductive portion, thereby converting heat energy to electrical energy.

Specifically, JP3981738B describes a thermoelectric conversion element in which flexible film substrates constituted of two kinds of materials having different thermal conductivities are provided on both surfaces of a thermoelectric conversion layer formed of a P-type material and an N-type material, and the materials having different thermal conductivities are located in opposite locations in the conduction direction on the external surface of the substrate.

JP2011-35205A describes an element having a sheet-like first insulating portion, a sheet-like second insulating portion, a plate-like thermoelectric conversion layer having a first end portion and a second end portion which are intended to draw a thermoelectric motive force that is stored between both insulating portions, a first highly thermal conductive portion which is disposed between the thermoelectric conversion layer and the first insulating portion, covers a first insulating portion side of the first end portion, and has a higher thermal conductivity than the first insulating portion, and a second highly thermal conductive portion which is disposed between a plate-like member and the second insulating portion, covers a second insulating portion side of the second end portion of the plate-like member, and has a higher thermal conductivity than the second insulating portion.

In the above-described thermoelectric conversion element, a temperature difference is caused in the surface direction of the thermoelectric conversion layer using the highly thermal conductive portions provided on the substrate, thereby converting heat energy to electrical energy. Therefore, it is possible to efficiently generate power by increasing the distance in which a temperature difference is caused even when the thermoelectric conversion layer is thin. Furthermore, since the thermoelectric conversion layer has a sheet form, it is possible to obtain a thermoelectric conversion module which has excellent flexibility and can be easily installed on curved surfaces and the like.

In the thermoelectric conversion elements described in JP3981738B and JP2011-35205A, basically, an inorganic material is used for the thermoelectric conversion layer. In contrast, WO2013/121486A describes a thermoelectric conversion element in which an organic material is used for the thermoelectric conversion layer in the same thermoelectric conversion element.

Specifically, WO2013/121486A describes a thermoelectric conversion element including a temperature difference-forming layer that causes a temperature difference in the horizontal direction, thermoelectric conversion layers formed on the temperature difference-forming layer, and a wire that connects the thermoelectric conversion layers, in which, in the temperature difference-forming layer, high thermal conductors having a smaller area on a main surface on a thermoelectric conversion layer side than on the other main surface and a low thermal conductor loaded into a gap between the high thermal conductors are alternately formed in the horizontal direction, and furthermore, the thermoelectric conversion layers are formed so as to cover at least some of the high thermal conductors and extend up to the low thermal conductor adjacent to the high thermal conductors.

### SUMMARY OF THE INVENTION

It is well known that organic materials have a lower thermal conductivity than inorganic materials. Therefore, for thermoelectric conversion elements for which an organic material is used, it is considered that the thermoelectric conversion elements become capable of obtaining a higher power generation efficiency when a temperature difference is caused in the surface direction of a thermoelectric conversion layer, and thus heat energy is converted to electrical energy as described in WO2013/121486A.

Furthermore, when an organic material is used for the thermoelectric conversion layer in the thermoelectric conversion element, it is possible to obtain a thermoelectric conversion element having superior flexibility.

However, according to studies by the present inventors, it was found that, in a case in which a thermoelectric conversion layer made of an organic material is used in a thermoelectric conversion element in which a temperature difference is caused in the surface direction of the thermoelectric conversion layer using highly thermal conductive portions on a substrate, thereby converting heat energy to electrical energy, the electrical conductivity of the thermoelectric conversion layer is important in order to obtain a high thermoelectric conversion efficiency.

An object of the present invention is to solve the above-described problem of the related art and to provide a thermoelectric conversion element in which a temperature difference is caused in the surface direction of a thermoelectric conversion layer using highly thermal conductive portions on a substrate, thereby converting heat energy to electrical energy and which has the thermoelectric conversion layer made of an organic material and has a higher thermoelectric conversion efficiency.

In order to achieve the above-described object, a thermoelectric conversion element of the present invention has a first substrate having a highly thermal conductive portion having a higher thermal conductivity than other regions in at least a part thereof in a surface direction; a thermoelectric conversion layer which is formed on the first substrate, is made of an organic material, and has a higher electrical conductivity in the surface direction than in a thickness direction; a second substrate which is formed on the thermoelectric conversion layer and has a highly thermal conductive portion which has a higher thermal conductivity than other regions in at least a part thereof in the surface direction and in which the highly thermal conductive portion does not fully overlap the highly thermal conductive portion of the first substrate in the surface direction; and a pair of electrodes that are connected to the thermoelectric conversion layer so as to sandwich the thermoelectric conversion layer in the surface direction.

In the above-described thermoelectric conversion element of the present invention, a ratio of the electrical conductivity in the surface direction to that in the thickness direction of the thermoelectric conversion layer is preferably higher than 10 (the electrical conductivity in the surface direction:the electrical conductivity in the thickness direction>10:1).

In addition, the ratio of the electrical conductivity in the surface direction to that in the thickness direction of the thermoelectric conversion layer is preferably higher than 100 (the electrical conductivity in the surface direction:the electrical conductivity in the thickness direction>100:1).

In addition, the thermoelectric conversion layer preferably includes a carbon nanotube.

In addition, the thermoelectric conversion layer is preferably formed by dispersing the carbon nanotube in a resin material.

In addition, the thermoelectric conversion layer preferably contains the carbon nanotube and a surfactant.

In addition, it is preferable that the carbon nanotube is a single-wall carbon nanotube and has a length of 1 μm or longer.

In addition, the thermoelectric conversion layer preferably includes a conductive polymer.

In addition, the conductive polymer is preferably poly(3,4-ethylenedioxythiophene).

In addition, the highly thermal conductive portion in the first substrate and the highly thermal conductive portion in the second substrate are preferably provided at different locations in a separation direction of the electrodes in the surface direction.

In addition, the highly thermal conductive portion in the first substrate and the highly thermal conductive portion in the second substrate are preferably located on an external surface with respect to a lamination direction.

In addition, an adhesive layer is preferably provided between the first substrate and the electrode pair.

In addition, a gas barrier layer covering the thermoelectric conversion layer and the electrode pair is preferably provided.

In addition, an end surface of the thermoelectric conversion layer in the surface direction preferably has a tapered shape.

In addition, each electrode of the electrode pair is preferably formed so as to extend to a top surface from the end surface of the thermoelectric conversion layer in the surface direction.

Furthermore, it is preferable that a forming material of the electrode pair is gold and a buffer layer is provided between at least one electrode of the electrode pair and the thermoelectric conversion layer.

In addition, a method for manufacturing a thermoelectric conversion element of the present invention has a step of treating a solution including at least a carbon nanotube and a dispersion medium using a high-speed spin thin film dispersion method and preparing a carbon nanotube (CNT) coating fluid by dispersing the carbon nanotube in the dispersion medium; a step of applying and drying the CNT coating fluid on a first substrate having a highly thermal conductive portion having a higher thermal conductivity than other regions in at least a part thereof in a surface direction, thereby forming a thermoelectric conversion layer; a step of connecting an electrode pair to the thermoelectric conversion layer so as to sandwich the thermoelectric conversion layer in the surface direction; and a step of laminating a second substrate which has a highly thermal conductive portion having a higher thermal conductivity than other regions in at least a part thereof in the surface direction and in which the highly thermal conductive portion does not fully overlap the highly thermal conductive portion of the first substrate in the surface direction on the thermoelectric conversion layer.

In the above-described method for manufacturing a thermoelectric conversion element of the present invention, the dispersion medium including the CNT coating fluid is preferably a resin material.

In addition, it is preferable that the dispersion medium included in the CNT coating fluid is water and the CNT coating fluid contains a surfactant.

Furthermore, it is preferable that, in the step of forming the thermoelectric conversion layer, the CNT coating fluid is applied to the first substrate by means of printing.

According to the present invention, in the thermoelectric conversion element in which a temperature difference is caused in the surface direction of the thermoelectric conversion layer using the highly thermal conductive portions on a substrate, thereby converting heat energy to electrical energy, the thermoelectric conversion layer which is made of an organic material and is anisotropic so that the electrical conductivity is higher in the surface direction than in the thickness direction is provided, and thus a thermoelectric conversion element in which a direction in which a temperature difference is caused and a conduction direction are coincided with each other and thus the power generation efficiency is higher can be obtained.

### BRIEF DESCRIPTION OF THE DRAWINGS

FIG. 1A is a top view schematically illustrating an example of a thermoelectric conversion element of the present invention, FIG. 1B is a front view thereof, and FIG. 1C is a bottom view thereof.

FIG. 2A is a top view schematically illustrating another example of the thermoelectric conversion element of the present invention, FIG. 2B is a front view thereof, and FIG. 2C is a bottom view thereof.

FIGS. 3A and 3B are views schematically illustrating additional examples of a thermoelectric conversion layer in the thermoelectric conversion element of the present invention.

FIGS. 4A to 4D are schematic views for describing an example of a thermoelectric conversion module in which the thermoelectric conversion element of the present invention is used.

FIG. 5 is a schematic view for describing a thermoelectric conversion module produced using a thermoelectric conversion element of the related art which is produced in an example of the present invention.

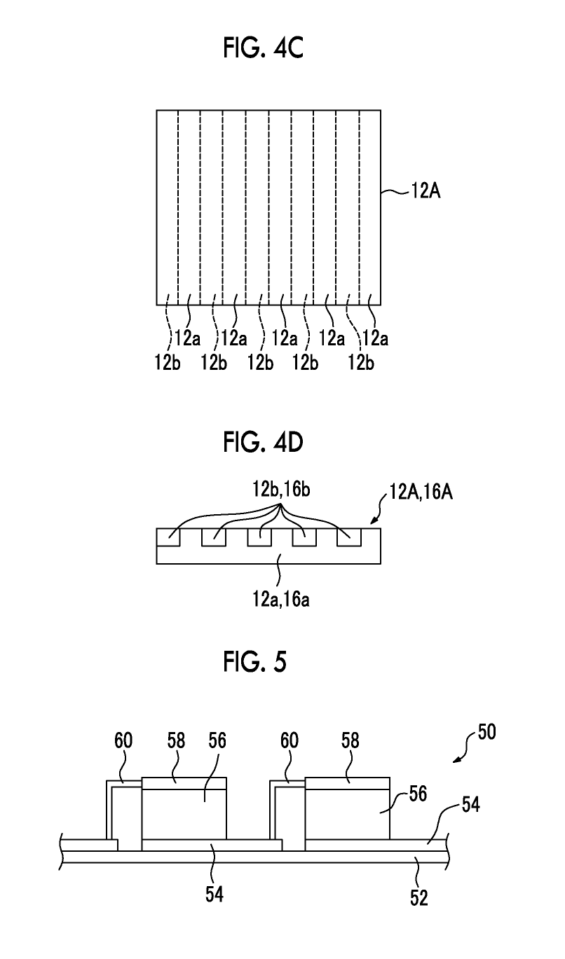

### DESCRIPTION OF THE PREFERRED EMBODIMENTS

Hereinafter, a thermoelectric conversion element and a method for manufacturing a thermoelectric conversion element of the present invention will be described in detail on the basis of preferred examples illustrated in the accompanying drawings.

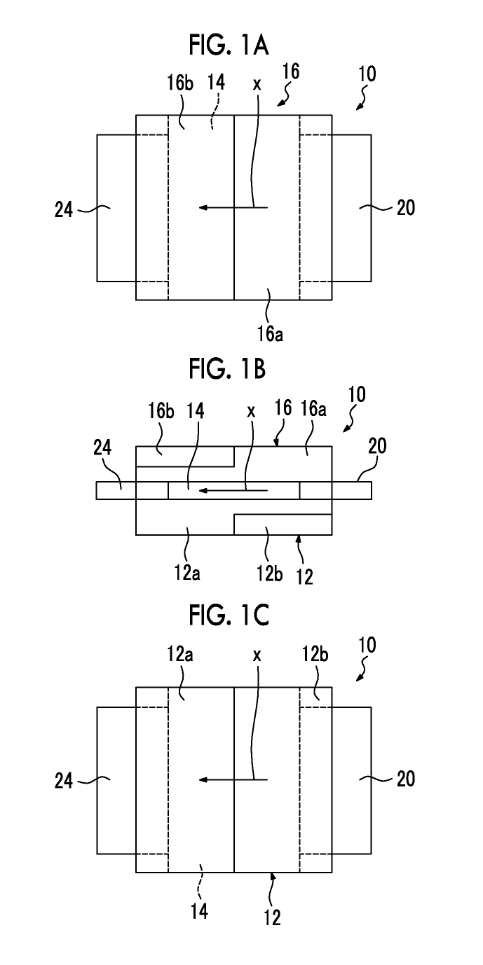

FIGS. 1A to 1C schematically illustrate an example of the thermoelectric conversion element of the present invention. Meanwhile, FIG. 1A is a top view thereof (a view of the thermoelectric conversion element in FIG. 1B seen from above), FIG. 1B is a front view thereof (a view of the thermoelectric conversion element seen from a substrate or the like described below in a surface direction), and FIG. 1C is a bottom view thereof (a view of the thermoelectric conversion element in FIG. 1B seen from below).

A thermoelectric conversion element 10 illustrated in FIGS. 1A to 1C is basically constituted of a first substrate 12, a thermoelectric conversion layer 14, a second substrate 16, an electrode 20, and an electrode 24.

Specifically, the thermoelectric conversion layer 14 is provided on the first substrate 12, the second substrate 16 is provided on the thermoelectric conversion layer 14, and the electrode 20 and the electrode 24 (electrode pair) are connected to the thermoelectric conversion layer 14 so as to sandwich the thermoelectric conversion layer 14 in a surface direction between the first substrate 12 and the second substrate 16.

As illustrated in FIGS. 1A to 1C, the first substrate 12 has a poorly thermal conductive a and a highly thermal conductive portion 12b. Similarly, the second substrate 16 also has a poorly thermal conductive portion 16a and a highly thermal conductive portion 16b. In the example illustrated in the drawings, both substrates are disposed so that the highly thermal conductive portions thereof are located at different positions in a connection direction of the electrode 20 and the electrode 24. The connection direction of the electrode 20 and the electrode 24 is, that is, a conduction direction.

Although both substrates have different disposal positions and different orientations of the front surface and the rear surface or the surface direction, the constitutions thereof are identical to each other, and thus the first substrate 12 will be described as a typical example unless it is necessary to differentiate the first substrate 12 and the second substrate 16. The surface direction refers to the direction of the substrate surface.

In the thermoelectric conversion element 10 in the example illustrated in the drawings, the first substrate 12 (the second substrate 16) has a constitution in which a recessed portion is formed in a region half as large as one surface of a rectangular plate-like article (sheet-like article) which serves as the poorly thermal conductive portion 12a (poorly thermal conductive portion 16a) and the highly thermal conductive portion 12b (the highly thermal conductive portion 16b) is fitted into the recessed portion so as to form a uniform surface.

Therefore, on one surface of the first substrate 12, a half region in the surface direction serves as the poorly thermal conductive portion 12a and the remaining half region serves as the highly thermal conductive portion 12b.

As the poorly thermal conductive portion 12a, it is possible to use articles made of a variety of materials such as a glass plate, a ceramic plate, and a plastic film as long as the articles have insulation properties and are heat-resistant enough to withstand the formation and the like of the thermoelectric conversion layer 14, the electrode 20, and the like.

Preferably, a plastic film is used as the poorly thermal conductive portion 12a. When a plastic film is used as the poorly thermal conductive portion 12a, weight reduction or cost reduction can be achieved and, furthermore, it becomes possible to form a flexible thermoelectric conversion element 10, which is preferable.

Specific examples of the plastic film that can be used for the poorly thermal conductive portion 12a include films (sheet-like articles/plate-like articles) made of a polyester resin such as polyethylene terephthalate, polyethylene isophthalate, polyethylene naphthalate, polybutylene terephthalate, poly(1,4-cyclohexylene dimethylene terephthalate), or polyethylene-2,6-naphthalene dicarboxylate, a resin such as polyimide, polycarbonate, polypropylene, polyether sulfone, cycloolefin polymer, polyether ether ketone (PEEK), or triacetyl cellulose (TAC), glass epoxy, liquid crystalline polyester, or the like.

Among these, from the viewpoint of thermal conductivity, heat resistance, solvent resistance, ease of procurement, economic efficiency, and the like, films made of polyimide, polyethylene terephthalate, polyethylene naphthalene, or the like are preferably used.

As the highly thermal conductive portion 12b, it is possible to use, for example, films (sheet-like articles/plate-like articles) made of a variety of materials as long as the films have a higher thermal conductivity than the poorly thermal conductive portion 12a.

Specific examples of the materials include a variety of metals such as gold, silver, copper, and aluminum from the viewpoint of thermal conductivity and the like. Among these, from the viewpoint of thermal conductivity, economic efficiency, and the like, copper and aluminum are preferably used.

In the present invention, the thickness of the first substrate 12 (the poorly thermal conductive portion 12a in a region in which the highly thermal conductive portion 12b is absent), the thickness of the poorly thermal conductive portion 12a, and the like may be appropriately set depending on the forming materials of the highly thermal conductive portion 12b and the poorly thermal conductive portion 12a, the size of the thermoelectric conversion element 10, and the like.

The size of the first substrate 12 in the surface direction (when seen in a direction orthogonal to the substrate surface), the area ratio in the surface direction of the highly thermal conductive portion 12b to the substrate 12, and the like may also be appropriately set depending on the forming materials of the highly thermal conductive portion 12b and the poorly thermal conductive portion 12a, the size of the thermoelectric conversion element 10, and the like.

The position of the highly thermal conductive portion 12b in the surface direction in the first substrate 12 is also not limited to that in the example illustrated in the drawings, and the highly thermal conductive portion can be located at a variety of positions.

For example, in the first substrate 12, the highly thermal conductive portion 12b may be included in the poorly thermal conductive portion 12a in the surface direction or may have a part in the surface direction located at an end portion and be included in the poorly thermal conductive portion in the remaining region (a part of the outer circumference in the surface direction may be in contact with the poorly thermal conductive portion 12a). Furthermore, the first substrate 12 may have a plurality of highly thermal conductive portions 12b in the surface direction.

Meanwhile, in the thermoelectric conversion element 10 illustrated in FIGS. 1A to 1C, as a preferred aspect in which a temperature difference is easily caused between the first substrate 12 and the second substrate 16, both the highly thermal conductive portion 12b and the highly thermal conductive portion 16b are located outside in a lamination direction in the first substrate 12 and the second substrate 16.

However, in the present invention, in addition to the above-described constitution, a constitution in which both the highly thermal conductive portion 12b and the highly thermal conductive portion 16b are located inside in the lamination direction in the first substrate 12 and the second substrate 16 may be employed. Alternatively, a constitution in which the highly thermal conductive portion 12b is located outside in the lamination direction in the first substrate 12 and the highly thermal conductive portion 16b is located inside in the lamination direction in the second substrate 16 may be employed.

Meanwhile, in a case in which the highly thermal conductive portion is formed of a conductive material such as metal and is disposed inside in the lamination direction, it is necessary to form insulating layers or the like between the thermoelectric conversion layer 14 and the electrode 20 and the electrode 24 in order to ensure insulation properties therebetween.

In the thermoelectric conversion element 10, the thermoelectric conversion layer (heat generation layer) 14 is provided on the first substrate 12. The second substrate 16 is provided on the thermoelectric conversion layer 14. Meanwhile, as described above, the highly thermal conductive portions are located outside in the lamination direction in both substrates. Therefore, the thermoelectric conversion layer 14 is formed on a surface of the first substrate 12 on which the highly thermal conductive portion 12b is not exposed, and the second substrate 16 is laminated with a surface thereof on which the highly thermal conductive portion 16b is not exposed facing the thermoelectric conversion layer 14.

In the example illustrated in the drawings, the thermoelectric conversion layer is provided so that the center thereof in the surface direction coincides with the boundaries between the poorly thermal conductive portion and the highly thermal conductive portion in both substrates.

The electrode pair made up of the electrode 20 and the electrode 24 is connected to the thermoelectric conversion layer 14 so that the electrodes sandwich the thermoelectric conversion layer in the surface direction.

In the thermoelectric conversion element, a temperature difference is caused by, for example, bringing the thermoelectric conversion element into contact with a heat source so as to heat the thermoelectric conversion element, and a difference of the carrier density in the temperature difference direction is caused in the thermoelectric conversion layer 14 in accordance with the temperature difference, thereby generating electric power. In the example illustrated in the drawings, for example, a heat source is provided on the first substrate 12 side, and a temperature difference is caused between the first substrate 12 (particularly, the highly thermal conductive portion 12b) and the second substrate 16 (particularly, the highly thermal conductive portion 16b), thereby generating electric power. In addition, a wire is connected to the electrode 20 and the electrode 24, thereby drawing electric power (electrical energy) generated by means of heating or the like.

In the thermoelectric conversion element 10 of the present invention, the thermoelectric conversion layer 14 is basically made of an organic material, and a variety of constitutions in which a well-known thermoelectric conversion material is used can all be used as long as the thermoelectric conversion layer is anisotropic so that the electrical conductivity is high in the surface direction and low in the thickness direction as described below.

As the thermoelectric conversion material, specifically, an organic material such as a conductive polymer or a conductive nanocarbon material can be used.

Examples of the conductive polymer include polymer compounds having a conjugated molecular structure (conjugated polymers). The polymer having a conjugated molecular structure refers to a polymer having a structure in which, in a carbon-carbon bond on the main chain of the polymer, single bonds and double bonds are alternately connected to each other.

A conductive polymer that is used in the present invention does not need to be a high-molecular-weight compound at all times and may be an oligomer compound.

Specific examples of the conjugated polymer include thiophene-based compounds, pyrrole-based compounds, aniline-based compounds, acetylene-based compounds, p-phenylene-based compounds, p-phenylene vinylene-based compounds, p-phenylene ethynylene-based compounds, p-fluorenylene vinylene-based compounds, polyacene-based compounds, polyphenanthrene-based compounds, metal phthalocyanine-based compounds, p-xylylene-based compounds, vinylene sulfide-based compounds, m-phenylene-based compounds, naphthalene vinylene-based compounds, p-phenylene oxide-based compounds, phenyl ene sulfide-based compounds, furan-based compounds, selenophene-based compounds, azo-based compounds, metal complex-based compounds, and the like. In addition, conjugated polymers having a repeating unit derived from a monomer which is a derivative obtained by introducing a substituent into the above-described compound also can be used. These conjugated polymers may be used singly or in a combined form of two or more conjugated polymers.

Among these, thiophene-based compounds can be preferably used, and particularly, poly(3,4-ethylenedioxythiophene) (PEDOT) is preferably exemplified.

Specific examples of the conductive nanocarbon material include carbon nanotubes (hereinafter, also referred to as CNTs), carbon nanofibers, graphite, graphene, carbon nanoparticles, and the like. These conductive nanocarbon materials may be used singly or in a combined form of two or more conductive nanocarbon materials.

Among these, CNTs are preferably used since thermoelectric characteristics become more favorable.

Examples of CNTs include single-wall CNTs obtained by winding one carbon film (graphene sheet) around a tube in a cylindrical shape, double-wall CNTs obtained by winding two graphene sheets around a tube in a concentric shape, and multi-wall CNTs obtained by winding a plurality of graphene sheets around a tube in a concentric shape. In the present invention, each of the single-wall CNTs, the double-wall CNTs, and the multi-wall CNTs may be used singly or two or more CNTs may be jointly used. Particularly, the single-wall CNTs and the double-wall CNTs which have excellent conduction properties and semiconductor characteristics are preferably used, and the single-wall CNTs are more preferably used.

The single-wall CNTs may be semiconductor CNTs or metallic CNTs, and semiconductor CNTs and metallic CNTs may be jointly used. In a case in which both semiconductor CNTs and metallic CNTs are used, the content ratio of both CNTs in a composition can be appropriately adjusted depending on the usages of the composition. In addition, CNTs may include metal or the like, and CNTs including a molecule such as fullerene may be used.

The average length of CNTs that are used in the present invention is not particularly limited and can be appropriately selected depending on the usages of the composition. Specifically, although the average length also depends on the distance between the electrodes, the average length of CNTs is preferably in a range of 0.01 μm to 2,000 μm, more preferably in a range of 0.1 μm to 1,000 μm, and particularly preferably in a range of 1 μm to 1,000 μm from the viewpoint of ease of manufacturing, film-forming properties, conduction properties, and the like.

The diameter of CNT that is used in the present invention is not particularly limited but is preferably in a range of 0.4 nm to 100 nm, more preferably 50 nm or smaller, and particularly preferably 15 nm or smaller from the viewpoint of durability, transparency, film-forming properties, conduction properties, and the like.

Particularly, in a case in which the single-wall CNTs are used, the diameters thereof are preferably in a range of 0.5 nm to 2.2 nm, more preferably in a range of 1.0 nm to 2.2 nm, and particularly preferably in a range of 1.5 nm to 2.0 nm.

In some cases, CNTs with defects are included in CNTs in the obtained conductive composition. Since the defects of CNTs degrade the conduction properties of the composition, it is preferable to decrease the amount of the defects. The amount of CNTs with defects in the composition can be estimated using the ratio G/D of a G band to a D band in a Raman spectrum. It is possible to assume that, as the G/D ratio increases, the amount of defects in the CNT material decreases. In the present invention, the G/D ratio of the composition is preferably 10 or higher and more preferably 30 or higher.

In the present invention, modified or treated CNTs can also be used. Examples of a modification or treatment method include a method in which a ferrocene derivative or a nitrogen-substituted fullerene (azafulluerene) is added to CNTs, a method in which an alkali metal (potassium or the like) or a metallic element (indium or the like) is doped into CNTs using an ion doping method, a method in which CNTs are heated in a vacuum, and the like.

In a case in which CNTs are used, the thermoelectric conversion layer may include nanocarbon such as carbon nanohorn, carbon nanocoil, carbon nanobead, graphite, graphene, or amorphous carbon in addition to the single-wall CNTs or the multi-wall CNTs.

In a case in which CNTs are used in the thermoelectric conversion layer 14, the thermoelectric conversion layer preferably include a dopant.

As the dopant, a variety of well-known dopants can be used. Specifically, preferred examples of the dopant include alkali metals, hydrazine derivatives, metal hydrides (sodium borohydride, tetrabutylammonium borohydride, lithium aluminum hydride, and the like), polyethylene imine, halogens (iodine, bromine, and the like), Lewis acids (PF₅, AsF₅, and the like), protonic acids (hydrochloric acid, sulfuric acid, and the like), transition metal halides (FeCl₃, SnCl₄, and the like), organic electron-accepting materials (tetracyanoquinodimethane (TCNQ) derivatives, 2,3-dichloro-5,6-dicyano-p-benzoquinone (DDQ) derivatives, and the like), and the like. These dopants may be used singly or in a combined form of two or more dopants.

Among these, from the viewpoint of the stability of the material, the compatibility with CNTs, and the like, preferred examples thereof include polyethylene imine, organic electron-accepting materials such as TCNQ derivatives and DDQ derivatives.

In the thermoelectric conversion element 10 of the present invention, the thermoelectric conversion layer 14 obtained by dispersing the above-described thermoelectric conversion material in a resin material (binder) is preferably used.

More preferably, the thermoelectric conversion layer 14 obtained by dispersing a conductive nanocarbon material in a resin material is used. Particularly preferably, the thermoelectric conversion layer 14 obtained by dispersing CNTs in a resin material is used since a high conductivity can be obtained.

As the resin material, a variety of well-known nonconductive resin materials (polymers) can be used.

Specifically, it is possible to use a variety of well-known resin materials such as vinyl compounds, (meth)acrylate compounds, carbonate compounds, ester compounds, epoxy compounds, siloxane compounds, and gelatin.

More specifically, examples of the vinyl compounds include polystyrene, polyvinyl naphthalene, polyvinyl acetate, polyvinyl phenol, and polyvinyl butyral. Examples of the (meth)acrylate compounds include polymethyl (meth)acrylate, polyethyl (meth)acrylate, polyphenoxy (poly)ethylene glycol (meth) acrylate, polybenzyl (meth)acrylate, and the like. Examples of the carbonate compounds include bisphenol Z-type polycarbonate, bisphenol C-type polycarbonate, and the like. Examples of the ester compounds include amorphous polyesters.

Preferred examples thereof include polystyrene, polyvinyl butyral, the (meth)acrylate compounds, the carbonate compounds, and the ester compounds, and more preferred examples thereof include polyvinyl butyral, polyphenoxy (poly)ethylene glycol (meth) acrylate, polybenzyl (meth)acrylate, and amorphous polyesters.

In the thermoelectric conversion layer 14 obtained by dispersing the thermoelectric conversion material in the resin material, the amount ratio between the resin material and the thermoelectric conversion material in the thermoelectric conversion layer 14 may be appropriately set depending on materials being used, required thermoelectric conversion efficiencies, the viscosities or solid content concentrations of solutions having an influence on printing, and the like.

In the thermoelectric conversion element 10 of the present invention, as another constitution of the thermoelectric conversion layer 14, a thermoelectric conversion layer mainly made up of CNTs and a surfactant is also preferably used.

When the thermoelectric conversion layer 14 is constituted of CNTs and a surfactant, the thermoelectric conversion layer 14 can be formed using a coating composition to which a surfactant is added. Therefore, the thermoelectric conversion layer 14 can be formed using a coating composition in which CNTs are naturally dispersed. As a result, favorable thermoelectric conversion performance can be obtained using the thermoelectric conversion layer 14 which is long and includes a small number of defects and a large amount of CNTs.

As the surfactant, a well-known surfactant can be used as long as the surface has a function of dispersing CNTs. Specifically, a variety of surfactants can be used as long as the surfactants are dissoluble in water, polar solvents, or mixtures of water and a polar solvent and have a group that adsorbs CNTs.

Therefore, the surfactant may be an ionic surfactant or a non-ionic surfactant. The ionic surfactant may be a cationic surfactant, an anionic surfactant, or an amphoteric surfactant.

Examples of the anionic surfactant include alkyl benzene sulfonates such as dodecyl benzene sulfonic acid, aromatic sulfonic acid-based surfactants such as dodecyl phenyl ether sulfonate, mono soap-based anionic surfactants, ether sulfate-based surfactants, phosphate-based surfactants, carboxylic acid-based surfactants such as sodium deoxycholate and sodium cholate, water-soluble polymers such as carboxymethyl cellulose, salts thereof (sodium salt, ammonium salt, and the like), ammonium polystyrene sulfonate, and sodium polystyrene sulfonate, and the like.

Examples of the cationic surfactant include alkyl amine salts, quaternary ammonium salts, and the like. Examples of the amphoteric surfactant include alkyl betaine-based surfactants, amine oxide-based surfactants, and the like.

Examples of the non-ionic surfactant include sugar ester-based surfactants such as sorbitan aliphatic acid ester, aliphatic acid ester-based surfactants such as polyoxyethylene resin acid ester, ether-based surfactants such as polyoxyethylene alkyl ether, and the like.

Among these, the ionic surfactants are preferably used, and, among these, cholate or deoxycholate is preferably used.

In the thermoelectric conversion layer 14 mainly made up of CNTs and the surfactant, the mass ratio of the surfactant to CNTs is preferably 5 or lower and more preferably 2 or lower.

When the mass ratio of the surfactant to CNTs is 5 or lower, higher thermoelectric conversion performance can be obtained, which is preferable.

The thermoelectric conversion layer 14 mainly made up of CNTs and the surfactant may have an anti-foaming agent, a drying inhibitor, an antifungal agent, and the like as necessary.

Meanwhile, in a case in which the thermoelectric conversion layer 14 contains substances other than CNTs and the surfactant, the content thereof is preferably 20% by mass or less and more preferably 5% by mass or less.

In the thermoelectric conversion element 10 of the present invention, the thickness, the size in the surface direction, and the area ratio in the surface direction to the substrate of the thermoelectric conversion layer 14 may be appropriately set depending on the forming materials of the thermoelectric conversion layer 14, the size of the thermoelectric conversion element 10, and the like.

The electrode 20 and the electrode 24 are connected to the thermoelectric conversion layer 14 so as to sandwich the thermoelectric conversion layer in the surface direction. In the thermoelectric conversion element 10, the electrode 20 and the electrode 24 are connected to the thermoelectric conversion layer 14 in contact with end surfaces of the thermoelectric conversion layer 14.

The electrode 20 and the electrode 24 can be formed of a variety of materials as long as the materials have necessary conduction properties.

Specific examples thereof include metallic materials such as copper, silver, gold, platinum, nickel, chromium, and copper alloys, materials that are used as transparent electrodes in a variety of devices such as indium tin oxide (ITO) and zinc oxide (ZnO), and the like. Among these, copper, gold, platinum, nickel, copper alloys, and the like are preferably exemplified, and gold, platinum, and nickel are more preferably exemplified.

The thicknesses, sizes, and the like of the electrode 20 and the electrode 24 may also be appropriately set depending on the thickness of the thermoelectric conversion layer 14, the size of the thermoelectric conversion element 10, and the like.

In a case in which the electrode 20 and the electrode 24 are made of gold, buffer layers made of an electron-donating material or an electron-accepting material are preferably provided between the electrode 20 and the electrode 24 and the thermoelectric conversion layer 14. The buffer layer may be provided so as to come into contact with only one of the electrode 20 and the electrode 24, but the buffer layers are preferably provided so as to come into contact with both electrodes.

When the above-described buffer layers are provided, the resistance in the electrode interface decreases, and favorable thermoelectric conversion performance can be obtained, which is preferable.

For the buffer layer, a variety of electron-donating organic materials can be used.

Specifically, examples of low-molecular-weight materials include aromatic diamine compounds such as N,N′-bis(3-methylphenyl)-(1,1′-biphenyl)-4,4′-diamine (TPD) and 4,4′-bis [N-(naphthyl)-N-phenyl-amino]biphenyl (α-NPD), porphyrin compounds such as oxazole, oxadiazole, triazole, imidazole, imidazolone, stilbene derivatives, pyrazoline derivatives, tetrahydroimidazole, polyarylalkane, butadiene, 4,4′,4″ tris(N-(3-methylphenyl)N-phenylamino)triphenylamine (m-MTDATA), porphyrin, tetraphenyl porphyrin copper, phthalocyanine, copper phthalocyanine, and titanium phthalocyanine oxide, triazole derivatives, oxadiazole derivative, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, silazane derivatives, and the like.

In addition, examples of high-molecular-weight materials include polymers such as phenylenevinylene, fluorene, carbazole, indole, pyrene, pyrrole, picoline, thiophene, acetylene, diacetylene, and derivatives thereof.

Meanwhile, for the buffer layer, any compounds capable of sufficiently transporting holes can be used even when the compounds are not electron-donating compounds.

Specific examples thereof include compounds described in Paragraphs ‘0083’ to ‘0089’ of JP2008-72090A, ‘0043’ to ‘0063’ of JP2011-176259A, ‘0121’ to ‘0148’ of JP2011-228614A, and ‘0108’ to ‘0156’ of JP2011-228615A.

In addition, for the buffer layer, a variety of electron-donating inorganic materials can be used.

Examples of the electron-donating inorganic materials include calcium oxide, chromium oxide, copper chromium oxide, manganese oxide, cobalt oxide, nickel oxide, copper oxide, copper gallium oxide, copper strontium oxide, niobium oxide, molybdenum oxide, copper indium oxide, silver indium oxide, iridium oxide, and the like.

For the buffer layer, electron-accepting organic materials may be used.

Examples of the electron-accepting materials include oxadiazole derivatives such as 1,3-bis(4-tert-butylphenyl-1,3,4-oxadiazolyl)phenylene (OXD-7), tetracyanoquinodimethane (TCNQ) derivatives, anthraquinodimethane derivatives, diphenylquinone derivatives, bathocuproine, bathophenanthroline, derivatives thereof, triazole compounds, tris(8-hydroxyquinolinate)aluminum complexes, bis(4-methyl-8-quinolinate)aluminum complexes, distyrylarylene derivatives, silole compounds, and the like.

In addition, any materials capable of sufficiently transporting electrons can be used even when the compounds are not electron-accepting organic materials. Porphyrin-based compounds or styryl-based compounds such as 4-dicyanomethylene-2-methyl-6-(4-(dimethylaminostyryl))-4H pyrane (DCM), and 4H pyrane-based compounds can be used. Specific examples thereof include compounds described in Paragraphs ‘0073’ to ‘0078’ of JP2008-72090A.

The thickness (the thickness between the thermoelectric conversion layer and the electrode) of the buffer layer may be appropriately set depending on the forming material of the buffer layer to a thickness in which sufficient effects can be obtained. Specifically, the thickness of the buffer layer is preferably in a range of 0.05 nm to 100 nm and more preferably in a range of 0.5 nm to 10 nm.

In the thermoelectric conversion element 10 of the present invention, the thermoelectric conversion layer 14 is anisotropic in terms of electrical conductivity in the surface direction and in the thickness direction, and the electrical conductivity is higher in the surface direction than in the thickness direction.

In addition, in the thermoelectric conversion element 10 of the present invention, the highly thermal conductive portion 12b in the first substrate 12 and the highly thermal conductive portion 16b in the second substrate 16 do not fully overlap each other in the surface direction (when seen in a direction orthogonal to the substrate surface, both portions do not fully overlap each other).

As described above, both the first substrate 12 and the second substrate 16 have a constitution in which a poorly thermal conductive portion is formed in half of one surface and a highly thermal conductive portion is formed in the remaining half. In the example illustrated in the drawings, the highly thermal conductive portion 12b in the first substrate 12 and the highly thermal conductive portion 16b in the second substrate 16 are located in the surface direction so that the portions face each other in the conduction direction between the electrode 20 and the electrode 24 (the separation direction of both electrodes) and come into contact with each other at end portions thereof.

When the thermoelectric conversion element 10 of the present invention has the above-described constitution, it is possible to generate power by means of thermoelectric conversion at a high efficiency.

As well known, in thermoelectric conversion elements, a temperature difference is caused by bringing the thermoelectric conversion elements into contact with a heat source so as to heat the thermoelectric conversion elements, and a difference of the carrier density in the temperature difference direction is caused in the thermoelectric conversion layers in accordance with the temperature difference, thereby generating electric power. In the example illustrated in the drawings, for example, a heat source is provided on the first substrate 12 side, and a temperature difference is caused, thereby generating electric power.

In the thermoelectric conversion element 10 of the present invention, the first substrate 12 and the second substrate 16 have the highly thermal conductive portion 12b and the highly thermal conductive portion 16b respectively, and the highly thermal conductive portion 12b and the highly thermal conductive portion 16b do not overlap each other and are located at different positions in the surface direction. Therefore, for example, when a heat source is provided on the first substrate 12 side, as schematically illustrated using an arrow x in FIGS. 1A to 1C, a temperature difference is caused in the surface direction of the thermoelectric conversion layer 14 between the highly thermal conductive portion 12b and the highly thermal conductive portion 16b (heat flows in the surface direction of the thermoelectric conversion layer 14).

In the thermoelectric conversion element 10 of the present invention, the thermoelectric conversion layer 14 is formed of an organic material having a low thermal conductivity, and thus it is possible to efficiently generate electric power using a long distance of temperature difference in the surface direction (in-plane).

Here, according to studies by the present inventors, in order to generate electric power by means of more efficient thermoelectric conversion in the thermoelectric conversion element 10 in which a temperature difference is caused in the surface direction of the thermoelectric conversion layer 14, the electrical conductivity characteristics of the thermoelectric conversion layer 14 are important.

That is, in the thermoelectric conversion element 10 in which a temperature difference is caused in the surface direction of the thermoelectric conversion layer 14, it is possible to coincide a direction in which a temperature difference is caused in the thermoelectric conversion layer 14 with a direction of a high electrical conductivity, that is, the conduction direction of generated electricity by setting the electrical conductivity of the thermoelectric conversion layer 14 to be greater in the surface direction than in the thickness direction, whereby it is possible to improve the power generation efficiency.

Therefore, according to the thermoelectric conversion element 10 of the present invention, it is possible to generate electric power by means of thermoelectric conversion at an extremely high efficiency using the thermoelectric conversion layer 14 which is made of an organic material and has a low thermal conductivity, a long distance of temperature difference in the surface direction, and the synergetic effect of the coincidence of the temperature difference direction and the conduction direction in the thermoelectric conversion layer 14.

In the thermoelectric conversion element 10 of the present invention, the anisotropy of the electrical conductivity of the thermoelectric conversion layer 14, that is, the difference between the electrical conductivity of the thermoelectric conversion layer 14 in the surface direction (σ//[S/cm]) and the electrical conductivity in the thickness direction (σ⊥[S/cm]) is preferably great.

Specifically, the ratio of the electrical conductivity is preferably higher than 10 (the electrical conductivity in the surface direction:the electrical conductivity in the thickness direction (σ//:σ⊥)>10:1); more preferably higher than 100 (the electrical conductivity in the surface direction:the electrical conductivity in the thickness direction>100:1), and particularly preferably higher than 1,000 (the electrical conductivity in the surface direction:the electrical conductivity in the thickness direction>1,000:1).

When the anisotropy of the electrical conductivity of the thermoelectric conversion layer 14 is set in the above-described range, the power generation efficiency improvement effect obtained by coinciding the temperature difference direction and the conduction direction can be more preferably obtained.

In the thermoelectric conversion element 10 illustrated in the drawings, the highly thermal conductive portion 12b in the first substrate 12 and the highly thermal conductive portion 16b in the second substrate 16 are located at different positions in the surface direction in the separation direction of the electrode 20 and the electrode 24 (electrode pair) so that the portions face each other and come into contact with each other in the conduction direction between the electrode 20 and the electrode 24.

For the thermoelectric conversion element of the present invention, it is possible to use a variety of other constitutions as long as the highly thermal conductive portion in the first substrate and the highly thermal conductive portion in the second substrate do not fully overlap each other in the surface direction (when seen in a direction orthogonal to the substrate surface, both portions do not fully overlap each other).

For example, in the example illustrated in FIGS. 1A to 1C, both highly thermal conductive portions may be separated from each other in the separation direction of the electrode 20 and the electrode 24 in the surface direction by moving the highly thermal conductive portion 12b in the first substrate 12 to the right side of the drawing and moving the highly thermal conductive portion 16b in the second substrate 16 to the left side of the drawing. Specifically, the separation distance between the highly thermal conductive portion 12b in the first substrate 12 and the highly thermal conductive portion 16b in the second substrate 16 in the separation direction of the electrode 20 and the electrode 24 is preferably in a range of 10% to 90% and more preferably in a range of 10% to 50% of the size of the thermoelectric conversion layer 14 in the separation direction of the electrode 20 and the electrode 24 in the surface direction.

Alternatively, in a constitution in which the highly thermal conductive portions are separated from each other, it is also possible to provide protrusion portions which protrude toward the other side on the highly thermal conductive portion 12b and/or the highly thermal conductive portion 16b and thus make the highly thermal conductive portions in both substrates partially overlap each other in the surface direction.

Conversely, in the example illustrated in FIGS. 1A to 1C, the highly thermal conductive portions in both substrates may be overlapped each other in the surface direction by moving the highly thermal conductive portion 12b in the first substrate 12 to the left side of the drawing and moving the highly thermal conductive portion 16b in the second substrate 16 to the right side of the drawing.

In addition, in the present invention, it is possible to use a variety of other constitutions as long as the highly thermal conductive portion in the first substrate and the highly thermal conductive portion in the second substrate do not fully overlap each other in the surface direction.

For example, it is possible to form a highly thermal conductive portion having a circular shape in the first substrate, form a highly thermal conductive portion having a square shape with a side as long as the diameter of the circular shape in the second substrate, and dispose both substrates so that the centers of both highly thermal conductive portions are coincided with each other in the surface direction. In this constitution as well, although the distance is short, the end portions (circumferences) of both highly thermal conductive portions are located at different positions in the surface direction, and thus a temperature difference is caused in the surface direction in the thermoelectric conversion layer, and it is possible to generate electric power at a higher efficiency than in thermoelectric conversion elements in which a temperature difference is caused in the thickness direction.

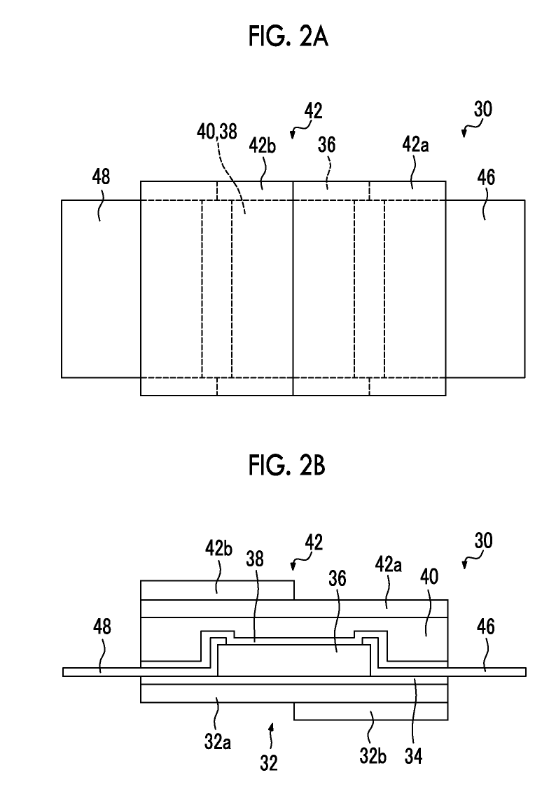

FIGS. 2A to 2C schematically illustrate another example of the thermoelectric conversion element of the present invention.

Meanwhile, similar to FIGS. 1A to 1C, FIG. 2A is a top view thereof, FIG. 2B is a front view thereof, and FIG. 2C is a bottom view thereof.

A thermoelectric conversion element 30 illustrated in FIGS. 2A to 2C is basically constituted of a first substrate 32, an adhesive layer 34, a thermoelectric conversion layer 36, a gas barrier layer 38, a gluing layer 40, a second substrate 42, an electrode 46, and an electrode 48.

Specifically, the adhesive layer 34 is provided on the first substrate 32, the thermoelectric conversion layer 36, the electrode 46, and the electrode 48 are provided on the adhesive layer 34, the gas barrier layer 38 covering the thermoelectric conversion layer 36, the electrode 46, and the electrode 48 is provided, the gluing layer 40 is provided on the gas barrier layer 38, and the second substrate 42 is provided on the gluing layer 40. The electrode 46 and the electrode 48 (electrode pair) are, similar to those in the previous example, provided so as to sandwich the thermoelectric conversion layer 36 in the surface direction.

The thermoelectric conversion element 30 has the adhesive layer 34, the gas barrier layer 38, and the gluing layer 40, and furthermore, the thermoelectric conversion element is basically the same as the above-described thermoelectric conversion element 10 except for the fact that the shapes of the substrates or the electrodes are different.

Similar to the thermoelectric conversion element 10, the first substrate 32 has a poorly thermal conductive portion 32a and a highly thermal conductive portion 32b. In addition, the second substrate 42 also has a poorly thermal conductive portion 42a and a highly thermal conductive portion 42b. The first substrate 32 and the second substrate 42 also have the same constitutions except for the fact that the disposition positions, orientations, and the like are different, and thus in the following description, the first substrate 32 will be described as a typical example.

The first substrate 12 has a constitution in which a recessed portion is formed in a part of the rectangular plate-like poorly thermal conductive portion 12a and the highly thermal conductive portion 12b is fitted into the recessed portion.

In contrast, the first substrate 32 (the second substrate 42) in the thermoelectric conversion element 30 has a constitution in which the highly thermal conductive portion 32b is laminated on the surface of the poorly thermal conductive portion 32a so as to cover the half surface of the rectangular plate-like (sheet-like) poorly thermal conductive portion 32a. The first substrate 32 is basically the same as the first substrate 12 except for the fact that the shape thereof is different.

The adhesive layer 34 is formed on the surface of the first substrate 32 on which the highly thermal conductive portion 32b is not formed.

The adhesive layer 34 is provided in order to, mainly, obtain adhesiveness between the first substrate 32 and the electrode 46 and the electrode 48.

For the adhesive layer 34, a variety of materials can be used depending on the forming material of the first substrate 32 (the poorly thermal conductive portion 32a), the electrode 46, and the electrode 48 as long as adhesiveness between both electrodes and the first substrate 32 can be ensured.

For example, in a case in which the electrode 46 and the electrode 48 are made of gold, silver, copper, or the like, examples of the adhesive layer 34 include layers made of silicon oxide (SiO₂), aluminum oxide (Al₂O₃), titanium oxide (TiO₂), chromium, titanium, or the like.

In a case in which the adhesive layer 34 is formed of silicon oxide or the like, it is possible to make the adhesive layer also serve as a gas barrier layer protecting the thermoelectric conversion layer 36 from moisture which has passed through the first substrate 32.

The thickness of the adhesive layer 34 may be appropriately set depending on the forming material and the like of the adhesive layer 34 to a thickness in which an intended adhering force between the electrode 46 and the electrode 48 can be obtained.

Specifically, the thickness thereof is preferably in a range of 10 nm to 1,000 nm and more preferably in a range of 50 nm to 200 nm.

When the thickness of the adhesive layer 34 is 10 nm or more, particularly, 50 nm or more, favorable adhesiveness between the electrode 46 and the electrode 48 and the first substrate 32 can be obtained, which is preferable.

When the thickness of the adhesive layer 34 is 1,000 nm or less, particularly, 200 nm or less, the thickness of the thermoelectric conversion element 30 (thermoelectric conversion module) can be reduced, a highly flexible thermoelectric conversion element 30 can be obtained, the flow rate of heat into the thermoelectric conversion layer 36 increases, and it is possible to improve the thermoelectric conversion performance of the thermoelectric conversion element 30, which is preferable.

The thermoelectric conversion layer 36, the electrode 46, and the electrode 48 are formed on the adhesive layer 34.

The thermoelectric conversion layer 36 is the same as the thermoelectric conversion layer 14. The electrode 46 and the electrode 48 are basically the same as the electrode 20 and the electrode 24 except for the fact that the shapes thereof are different.

The electrode 46 and the electrode 48 are provided so as to sandwich the thermoelectric conversion layer 36 in the surface direction.

Here, in the thermoelectric conversion element 30, the electrode 46 and the electrode 48 are formed so as to be not only in contact with the end surfaces of the thermoelectric conversion layer 36 in the surface direction but also continue from the end surface, extend over the top surface of the thermoelectric conversion layer 36, and cover the periphery of the end portion of the top surface. That is, the electrode 46 and the electrode 48 are formed so as to rise from the surface of the adhesive layer 34 and continue from the end surfaces of the thermoelectric conversion layer 36 so as to extend over the top surface of the thermoelectric conversion layer 36 and cover the periphery of the end portion of the top surface of the thermoelectric conversion layer 36.

In the thermoelectric conversion layer 36 in the thermoelectric conversion element 30 of the present invention, the electrical conductivity in the surface direction is higher than the electrical conductivity in the thickness direction. Therefore, in the thermoelectric conversion layer 36, the entry and extraction of electric current from the end surface is difficult.

In contrast, as illustrated in FIG. 2B, when the electrode 46 and the electrode 48 are formed so as to reach the periphery of the end portion of the top surface of the thermoelectric conversion layer 36 from the end surfaces of the thermoelectric conversion layer 36, the electrodes are made to cover the entire areas of the end surfaces of the thermoelectric conversion layer 36 in the thickness direction, and thus the entry and extraction of electric current into and from the end surfaces becomes easy, whereby the thermoelectric conversion performance can be improved. In addition, since the contact area between the thermoelectric conversion layer 36 and the electrode 46 and the electrode 48 is also increased, the resistance in the interface therebetween decreases, and, due to this fact, the thermoelectric conversion performance can be improved. Meanwhile, as long as the electrodes are not short-circuited, the electrodes may be formed so as to cover the top surface of the thermoelectric conversion layer 36.

The thermoelectric conversion element 30 has the gas barrier layer 38 covering the thermoelectric conversion layer 36, the electrode 46, and the electrode 48.

When the gas barrier layer 38 is provided, it is possible to prevent the thermoelectric conversion layer 36, the electrode 46, and the electrode 48 from deteriorating due to moisture and the like which have passed through the second substrate 42. In addition, when the gas barrier layer 38 is provided, the thermoelectric conversion layer 36, the electrode 46, and the electrode 48 are pressed down from above and thus reliably adhesion can be obtained, and, when the thermoelectric conversion element 30 (thermoelectric conversion module) is bent, it is possible to prevent the thermoelectric conversion layer 36, the electrode 46, and the electrode 48 from being damaged.

The gas barrier layer 38 can be formed of a variety of materials that develop gas barrier properties.

Examples thereof include films made of an inorganic compound such as a metal oxide such as aluminum oxide, magnesium oxide, tantalum oxide, zirconium oxide, titanium oxide, or indium tin oxide (ITO); a metal nitride such as aluminum nitride; a metal carbide such as aluminum carbide; a silicon oxide such as silicon oxide, silicon oxynitride, silicon oxycarbide, or silicon oxynitrocarbide; a silicon nitride such as silicon nitride or silicon nitrocarbide; a silicon carbide such as silicon carbide; a hydride thereof; a mixture of two or more thereof; or a hydrogen-containing substance thereof.

Particularly, silicon oxide, silicon nitride, silicon oxynitride, and aluminum oxide are preferably used since excellent gas barrier properties can be developed.

The thickness of the gas barrier layer 38 may be appropriately set depending on the forming material and the like of the gas barrier layer 38 to a thickness in which intended gas barrier performance can be obtained.

Specifically, the thickness of the gas barrier layer is preferably in a range of 10 nm to 1,000 nm and more preferably in a range of 50 nm to 200 nm.

When the thickness of the gas barrier layer 38 is set to 10 nm or more, particularly, 50 nm or more, favorable gas barrier properties can be obtained, which is preferable.

When the thickness of the gas barrier layer 38 is set to 1,000 nm or less, particularly, 200 nm or less, the thickness of the thermoelectric conversion element 30 (thermoelectric conversion module) can be reduced, and a highly flexible thermoelectric conversion element 30 can be obtained, which is preferable.

The gluing layer 40 is formed on the gas barrier layer 38. The gluing layer 40 is provided in order to glue the second substrate 42 with a sufficient adhering force.

As a forming material of the gluing layer 18, a variety of materials capable of gluing the gas barrier layer and the second substrate can be used depending on the forming materials of the gas barrier layer 38 (in a case in which the gas barrier layer 38 is not provided, the electrode and the thermoelectric conversion layer 36) and the second substrate 42 (the poorly thermal conductive portion 20a).

Specific examples thereof include acrylic resins, urethane resins, silicone resins, epoxy resins, rubber, EVA, α-olefin polyvinyl alcohol, polyvinyl butyral, polyvinyl pyrrolidone, gelatin, starch, and the like. In addition, the gluing layer 40 may be formed using commercially available double-sided tape or gluing films.

The thickness of the gluing layer 40 may be appropriately set depending on the forming material of the gluing layer 40, the degree of unevenness attributed to the thermoelectric conversion layer 36, and the like to a thickness in which the gas barrier layer 38 and the second substrate 42 can be glued to each other with a sufficient adhering force.

Specifically, the thickness of the gluing layer is preferably in a range of 5 μm to 100 μm and more preferably in a range of 5 μm to 50 μm.

When the thickness of the gluing layer 40 is set to 5 μm or more, it is possible to sufficiently fill the unevenness attributed to the thermoelectric conversion layer 36, and favorable adhesiveness can be obtained, which is preferable.

In addition, when the thickness of the gluing layer 40 is set to 100 μm or less, particularly, 50 μm or less, the thickness of the thermoelectric conversion element 30 (thermoelectric conversion module) can be reduced, a highly flexible thermoelectric conversion element 30 can be obtained, the thermal resistance of the gluing layer 40 can be reduced, and more favorable thermoelectric conversion performance can be obtained, which is preferable.

Meanwhile, if necessary, in order to improve the adhesiveness, in either or both the interface between the gas barrier layer 38 and the gluing layer 40 and the interface between the gluing layer 40 and the second substrate 42, the surface may be reformed or cleaned by carrying out a well-known surface treatment such as a plasma treatment, a UV ozone treatment, or an electron beam irradiation treatment on at least one surface out of the surfaces that form the interfaces.

Onto the gluing layer 40, the second substrate 42 is glued with a surface thereof which is fully the poorly thermal conductive portion 42a facing the gluing layer, thereby constituting the thermoelectric conversion element 30.

In the examples illustrated in FIGS. 1A to 1C and FIGS. 2A to 2C, the thermoelectric conversion layer 14 and the thermoelectric conversion layer 36 are rectangular plate-like articles (square shape). However, in the thermoelectric conversion element of the present invention, a variety of shapes can be used for the thermoelectric conversion layer.

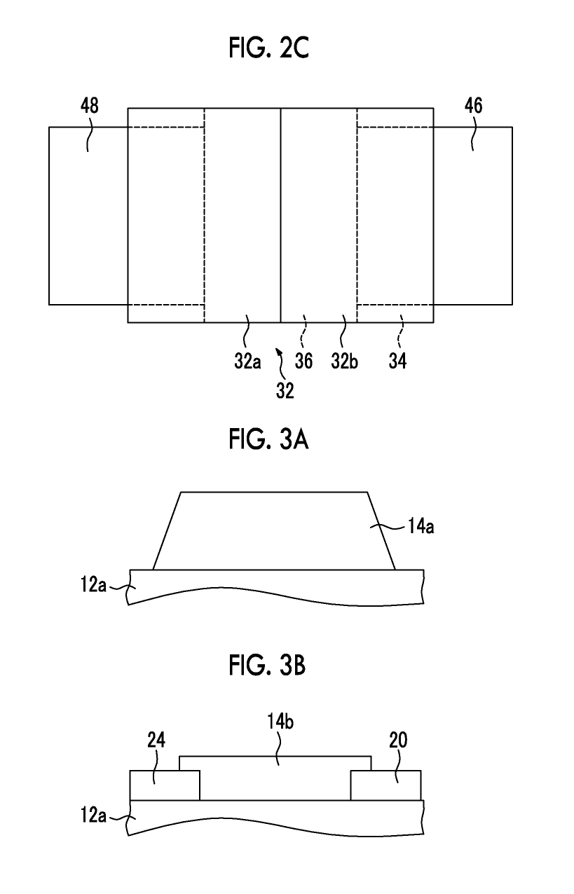

For example, as schematically illustrated in FIG. 3A using the thermoelectric conversion element 10 as an example, the thermoelectric conversion layer 14a may have a quadrangular pyramid shape. Alternatively, the thermoelectric conversion layer may have a cylindrical shape, a prismatic columnar shape other than rectangular, a conic shape, a truncated pyramid shape, an irregular shape, or the like.

In the thermoelectric conversion element of the present invention, in the thermoelectric conversion layer, the end surfaces in the surface direction preferably have a tapered shape as in a rectangular truncated pyramid shape or a conic shape which is illustrated by the thermoelectric conversion layer 14a illustrated in FIG. 3A. That is, the end surfaces of the thermoelectric conversion layer in the surface direction are preferably inclined toward the center of the thermoelectric conversion layer.

As described above, in the thermoelectric conversion layer in the thermoelectric conversion element 10 of the present invention, the electrical conductivity is higher in the surface direction and in the thickness direction. Therefore, in the thermoelectric conversion layer, the entry and extraction of electric current from the end surface is difficult.

In contrast, as in a thermoelectric conversion layer 14a illustrated in FIG. 3A, when a tapered shape is given to the end surfaces in the surface direction, it is possible to increase the contact area between the thermoelectric conversion layer 14a and the electrode 20 and the electrode 24. As a result, the resistance in the interface therebetween decreases, and thus the entry and extraction of electric current into and from the end surfaces becomes easy, whereby the thermoelectric conversion performance can be improved.

Meanwhile, even the thermoelectric conversion layer 14a of which the end surfaces in the surface direction have a tapered shape preferably has a constitution in which the electrodes partially cover the top surface of the thermoelectric conversion layer 14a as in the example illustrated in FIG. 2B.

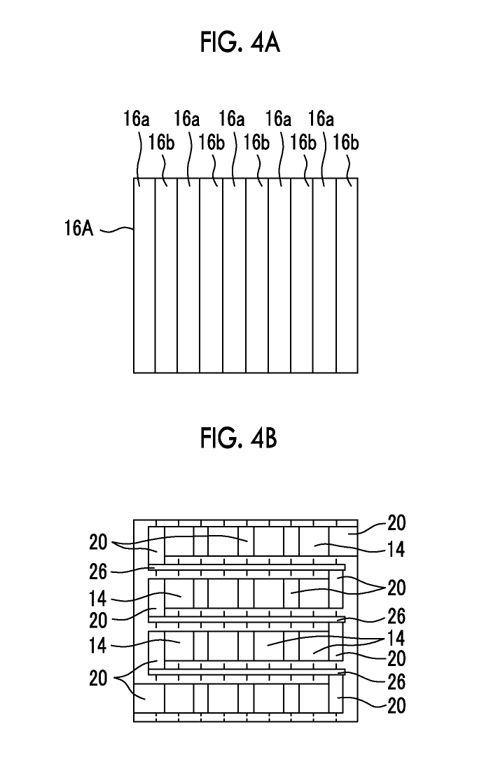

FIGS. 4A to 4D illustrate an example of a thermoelectric conversion module (power generation device) obtained by connecting a plurality of the thermoelectric conversion elements 10 illustrated in FIGS. 1A to 1C in series. Meanwhile, FIGS. 4A to 4C are top views, and FIG. 4D is a front view.

Meanwhile, a thermoelectric conversion module can be produced in the same manner using, the thermoelectric conversion element 30 illustrated in FIGS. 2A to 2C.

In the present example, a first substrate 12A and a second substrate 16A have a constitution in which grooves extending in the longitudinal direction are formed in a rectangular plate-like poorly thermal conductive material at intervals equal to the width of the groove in a direction orthogonal to the extension direction and a highly thermal conductive material is fitted into the grooves. That is, both substrates have a constitution in which poorly thermal conductive portions 12a and highly thermal conductive portions 12b, which uniaxially extend, are alternately formed on one surface at equal intervals in a direction orthogonal to the extension direction (refer to FIGS. 4A, 4C, and 4D).

As schematically illustrated in FIGS. 4B and 4C, the thermoelectric conversion layer 14 has a rectangular surface shape, and 4×4 (a total of 16) thermoelectric conversion layers are formed at equal intervals on a surface of the first substrate 12A on which the highly thermal conductive portions 12b are not exposed (a state in which the substrate in FIG. 4D is turned upside down in the vertical direction) so that the boundary between the poorly thermal conductive portion 12a and the highly thermal conductive portion 12b and the center of the thermoelectric conversion layer are coincided with each other.

In addition, the respective thermoelectric conversion layers 14 are connected to each other in series using the electrodes 20 (the electrodes 24) and connection wires 26. Specifically, as illustrated in FIG. 4B, in the arrangement of the thermoelectric conversion layers 14 in the horizontal direction of the drawing, the electrodes 20 are provided so as to sandwich each of the thermoelectric conversion layers 14 in the horizontal direction. Therefore, the respective thermoelectric conversion layers 14 are connected to each other through the electrodes 20 in the horizontal direction. Additionally, in the arrangement of the thermoelectric conversion layers 14 in the horizontal direction of the drawing, the electrode 20 at the left end of the uppermost tier and the electrode at the right end of the second tier are connected to each other through the connection wire 26, the electrode 20 at the left end of the second tier and the electrode 20 at the right end of the third tier are connected to each other through the connection wire 26, and furthermore, the electrode 20 at the left end of the third tier and the electrode 20 at the right end of the fourth tier are connected to each other through the connection wire 26.

Therefore, 16 thermoelectric conversion elements arranged in a 4×4 form are connected to each other in series in the horizontal direction in the drawing a unidirectional order.

Furthermore, as schematically illustrated in FIG. 4A, the second substrate 16A is laminated on the thermoelectric conversion layers 14 and the electrodes 20 so that the side of the second substrate on which the highly thermal conductive portions 16b are not exposed faces downward (the side faces the thermoelectric conversion layers 14, a state in which the substrate in FIG. 4D is rotated 180 degrees in the surface direction (the horizontal direction)) and the boundary between the poorly thermal conductive portion 12a and the highly thermal conductive portion 12b and the first substrate 12A are coincided with each other.

Therefore, the poorly thermal conductive portions 12a in the first substrate 12A and the highly thermal conductive portions 16b in the second substrate 16A correspondingly face each other in the surface direction, and the highly thermal conductive portions 12b in the first substrate 12A and the poorly thermal conductive portions 16a in the second substrate 16A correspondingly face each other in the surface direction.

Therefore, a thermoelectric conversion module formed by connecting 16 thermoelectric conversion elements 10 of the present invention in series is constituted.

Hereinafter, a method for manufacturing the thermoelectric conversion element of the present invention will be described in detail by describing an example of a method for manufacturing the thermoelectric conversion element 10 illustrated in FIGS. 1A to 1C.

First, a coating composition which is used to form the thermoelectric conversion layer 14 is prepared by adding an organic material made of a resin material to a dispersion medium (an organic solvent or water) and, furthermore, dispersing a thermoelectric conversion material such as CNT therein. Alternatively, a coating composition is prepared by adding and dispersing (dissolving) CNTs and a surfactant in water.

The dispersion and the preparation of the coating composition are preferably carried out using a high-speed spin thin film dispersion method.

The high-speed spin thin film dispersion method refers to a dispersion method in which a composition including a dispersion subject is rotated at a high speed in a state of being pressed in a thin film cylindrical shape on the internal surface of a device using a centrifugal force, and an abrasion stress generated due to a speed difference between the centrifugal force and the internal surface of the device is exerted on the composition containing the dispersion subject, thereby dispersing the dispersion subject in the composition having a thin film cylindrical shape.

Specifically, first, a thermoelectric conversion material such as CNT and a resin material (a dispersion medium (binder)) are preliminarily mixed together, thereby preparing a preliminary mixture. Alternatively, CNTs and a surfactant are added to water which is a dispersion medium (dispersant) and are preliminarily mixed together, thereby preparing a preliminary mixture. As the water, pure water (ion-exchange water) or ultrapure water is preferably used.

To this preliminary mixture, if necessary, a variety of components such as a dispersant, a non-conjugated polymer, a dopant, and a thermal excitation assist agent may be added.

The preliminary mixing may be carried out using an ordinary mixing device.

Next, the preliminary mixture is treated using the high-speed spin thin film dispersion method, thereby preparing a coating composition which is obtained by dispersing a thermoelectric conversion material such as CNT in a resin material and is used to form the thermoelectric conversion layer 14. Alternatively, the preliminary mixture is treated using the high-speed spin thin film dispersion method, thereby preparing a coating composition which is obtained by dispersing (dissolving) CNTs and a surfactant in water and is used to form the thermoelectric conversion layer 14.

The high-speed spin thin film dispersion method can be carried out using, for example, a device including a tubular cover having a circular section, a tubular stirring blade that is disposed in the tubular cover so as to be capable of rotating concentrically with the tubular cover, and an injection pipe having an opening below the stirring blade, in which the stirring blade has an outer circumferential surface that faces the inner circumferential surface of the tubular cover with a slight gap therebetween and a number of through holes that penetrate a tubular wall of the stirring blade in the thickness direction. Preferred examples of the above-described device include thin film spin high-speed mixer “FILMIX” (registered trademark) series (manufactured by PRIMIX Corporation).

When the above-described device is used, it is possible to prepare a coating composition which is used to form the thermoelectric conversion layer 14 by rotating a thermoelectric conversion material such as CNT at a high speed using a centrifugal force in a state of being pressed in a thin film cylindrical shape on the internal surface of a device and exerting an abrasion stress generated due to the speed difference between the centrifugal force and the internal surface of the device on the preliminary mixture, thereby dispersing the thermoelectric conversion material in the preliminary mixture having a thin film cylindrical shape.

According to the above-described high-speed spin thin film dispersion method, CNTs can be dispersed in a resin material without being cut. Therefore, when the thermoelectric conversion layer 14 is formed using a coating composition prepared using the high-speed spin thin film dispersion method, it is possible to form the thermoelectric conversion layer 14 in which CNTs having a length of 1 μm or longer are dispersed. Therefore, it is possible to form the thermoelectric conversion layer 14 in which the ratio of the electrical conductivity is higher than 10 (the electrical conductivity in the surface direction:the electrical conductivity in the thickness direction>10:1), preferably higher than 100 (the electrical conductivity in the surface direction:the electrical conductivity in the thickness direction>100:1), and more preferably higher than 1,000 (the electrical conductivity in the surface direction:the electrical conductivity in the thickness direction>1,000:1).

Meanwhile, the first substrate 12 (12A) having the poorly thermal conductive portion 12a and the highly thermal conductive portion 12b and the second substrate 16 (16A) having the poorly thermal conductive portion 16a and the highly thermal conductive portion 16b are prepared.

As the first substrate 12 and the second substrate 16, commercially available substrates may be used. Alternatively, the first substrate 12 and the second substrate 16 may be produced using a well-known method such as photolithography, etching, a film-forming technique.

Meanwhile, as the first substrate 32 (the second substrate 42) as illustrated in FIGS. 2A to 2C, for example, the first substrate 32 obtained by laminating the highly thermal conductive portion 32b on the poorly thermal conductive portion 32a may be produced by gluing the sheet-like (or band-like) highly thermal conductive portion 32b to a sheet-like article which serves as the poorly thermal conductive portion 32a. Alternatively, the first substrate 32 obtained by laminating the highly thermal conductive portion 32b on the poorly thermal conductive portion 32a may be produced by preparing a sheet-like article obtained by forming a layer which serves as the highly thermal conductive portion 32b on the entire surface of a sheet-like article which serves as the poorly thermal conductive portion 32a and etching the layer which serves as the highly thermal conductive portion 32b so as to remove an unnecessary portion.

The prepared coating composition which is used to form the thermoelectric conversion layer 14 is applied in a pattern in accordance with the thermoelectric conversion layer 14 on a surface of the first substrate 12 on which the highly thermal conductive portion 12b is not formed. The coating composition may be applied using a well-known method such as a method in which a mask is used or a printing method.

After the coating composition is applied, the coating composition is dried and cured using a method suitable for the resin material, thereby forming the thermoelectric conversion layer 14. Meanwhile, if necessary, after the coating composition is dried, the coating composition (the resin material) may be cured by means of the irradiation with ultrasonic rays or the like.

Alternatively, the thermoelectric conversion layer 14 may be formed in a pattern by applying, drying, and then etching the prepared coating composition which is used to form the thermoelectric conversion layer 14 on the entire surface of the first substrate 12 on which the highly thermal conductive portion 12b is not formed.

In the present invention, the thermoelectric conversion layer 14 is preferably formed in a pattern by means of printing.

When the thermoelectric conversion layer is formed in a pattern by means of printing, it is possible to easily and preferably form the thermoelectric conversion layer 14a having the end surfaces in the surface direction with a tapered shape as illustrated in FIG. 3A.

As a printing method, a variety of printing methods such as screen printing, metal mask printing, or stencil printing.

Next, the electrode 20 and the electrode 24 are formed so as to sandwich the thermoelectric conversion layer 14 in the surface direction.

The electrode 20 and the electrode 24 may be formed using a well-known method depending on the forming materials and the like of the electrode 20 and the electrode 24.

Furthermore, the prepared second substrate 16 is glued to the thermoelectric conversion layer 14 with the side on which the highly thermal conductive portion 16b is not formed facing the thermoelectric conversion layer, thereby producing the thermoelectric conversion element 10.

Meanwhile, the thermoelectric conversion element 10 may be produced by applying the coating composition which is used to form the thermoelectric conversion layer 14 to the first substrate 12, then, forming the electrode 20 and the electrode 24 in a state in which the coating composition is semi-cured, furthermore, laminating the second substrate 16 thereon, and the fully curing the coating composition.

In the above-described example, the electrode 20 and the electrode 24 are formed after the thermoelectric conversion layer 14 is formed, but the thermoelectric conversion layer 14 and the electrode 20 and the electrode 24 may be formed in the opposite order.

In this case, like the thermoelectric conversion layer 14b which is schematically illustrated in FIG. 3B, the end portions of the thermoelectric conversion layer may cover the end portions of the electrode 20 and the electrode 24.

Meanwhile, in a case in which the thermoelectric conversion element 30 illustrated in FIGS. 2A to 2C is produced, first, the adhesive layer 34 is formed on the surface of the first substrate 32 on which the highly thermal conductive portion 32b is not formed (the surface on which only the poorly thermal conductive portion 32a exists) before the formation of the thermoelectric conversion layer 36.

The adhesive layer 34 may be formed using a well-known method depending on the forming material of the adhesive layer 34. For example, in a case in which the adhesive layer 34 is made of silicon oxide, the adhesive layer 34 may be formed using an electron beam (EB) deposition method or sputtering.

Next, similar to what has been described above, after the thermoelectric conversion layer 36, the electrode 46, and the electrode 48 are formed, the gas barrier layer 38 is formed. The gas barrier layer 38 may also be formed using a well-known method. For example, in a case in which the gas barrier layer 38 is made of silicon oxide, similar to what has been described above, the gas barrier layer 38 may be formed using an EB deposition method or sputtering.

Next, the gluing layer 40 is formed on the gas barrier layer 38. The gluing layer 40 may also be formed using a well-known method such as a coating method depending on the forming material of the gluing layer. Alternatively, the gluing layer 40 may be formed using double-sided gluing tape.

Finally, the second substrate 42 is glued to the gluing layer 40 with the surface of the second substrate which is fully the poorly thermal conductive portion 42a facing toward the gluing layer 40, thereby producing the thermoelectric conversion element 30 (thermoelectric conversion module).

When electric power is generated by bringing the thermoelectric conversion element 30 (thermoelectric conversion module) of the present invention into contact with a heat source or adhering the thermoelectric conversion element to a heat source, a thermal conductive adhesive sheet and/or a heat-dissipating fin may be jointly used.

A thermal conductive adhesive sheet that is used after being attached to the heating side or the cooling side of the module is not particularly limited, and a commercially available heat-dissipating sheet can be used. Examples thereof include TC-50TXS2 manufactured by Shin-Etsu Chemical Co., Ltd., hyper soft heat-dissipating material 5580H manufactured by 3M Japan Limited, BFG20A manufactured by Denka Company Limited., TR5912F manufactured by Nitto Denko Corporation, and the like. Meanwhile, from the viewpoint of heat resistance, a thermal conductive adhesive sheet made of a silicone-based gluing agent is preferred.

When the thermal conductive adhesive sheet is used, it is possible to increase the power generation amount due to the following effects: (1) the adhesiveness to the heat source improves, and the surface temperature on the heating side of the module increases, (2) the cooling efficiency improves, and it is possible to lower the surface temperature on the cooling side of the module, and the like.

In addition, on the surface on the cooling side of the thermoelectric conversion element 30 (thermoelectric conversion module), a heat-dissipating fin or a heat sink which is made of a well-known material such as stainless steel, copper, or aluminum, may be provided.

When the heat-dissipating fin is used, it is possible to more preferably cool the low-temperature side of the thermoelectric conversion element, the temperature difference increases, and the power generation efficiency further improves, which is preferable.

The thermoelectric conversion element of the present invention can be used for a variety of usages.

Examples thereof include a variety of power generation usages such as power generators such as spring heat power generators, solar heat power generators, and waste heat power generators and power supplies for a variety of devices such as power supplies for wrist watches, semiconductor-driving power supplies, and power supplies for small-sized sensors. In addition, examples of the usages of the thermoelectric conversion element of the present invention also include, in addition to the power generation usages, sensor element usages such as heat-sensitive sensors and thermocouples.

Hitherto, the thermoelectric conversion element and the method for manufacturing the thermoelectric conversion element of the present invention have been described in detail, but the present invention is not particularly limited to the above-described examples, and it is needless to say that the present invention may be improved or modified in various manners within the scope of the gist of the present invention.

### EXAMPLES

Hereinafter, the thermoelectric conversion element of the present invention will be described in more detail using specific examples of the present invention. However, the present invention is not limited to the following examples.

### Example 1

### Preparation of Coating Composition Used to Form Thermoelectric Conversion Layer

<<Synthesis of Resin>>

Methyl methacrylate (100 g) and thiopropionic acid (0.35 g) were injected into a 250 mL three-neck flask and were heated at 80° C. After the heating, azobisisobutyronitrile (AIBN, manufactured by Wako Pure Chemical Industries, Ltd., 17 mg) was injected thereinto, the components were reacted with each other for 40 minutes, then, AIBN (17 mg) was repeatedly injected thereinto twice, and the components were reacted with each other for 40 minutes. After that, tetrahydrofuran (10 g) was injected thereinto, and the reaction was finished. The reaction liquid was redeposited, thereby obtaining an intermediate body A (60 g).

The obtained intermediate body A (15 g), xylene (30 g), glycidyl methacrylate (0.28 g), hydroquinone (0.01 g), and dimethyl laurylamine (0.01 g) were injected into a 250 mL three-neck flask and were reacted for five hours under reflux conditions. After that, the reaction liquid was redeposited, thereby obtaining a macromonomer (10 g) of polymethyl methacrylate (PMMA).

2-Hydroxyethyl methacrylate (0.27 g), the macromonomer of PMMA synthesized above (4 g), and dimethyl acetoamide (8 g) were injected into a 300 mL three-neck flask and were heated at 80° C. After that, a polymerization initiator (manufactured by Wako Pure Chemical Industries, Ltd., V-601, 0.0127 g) was injected thereinto, and the components were reacted with each other for two hours. Furthermore, the step of injecting the same polymerization initiator (0.0127 g) and reacting the components with each other for two hours was repeated twice.

The obtained reaction liquid was redeposited, thereby obtaining a resin represented by the following formula (3 g).

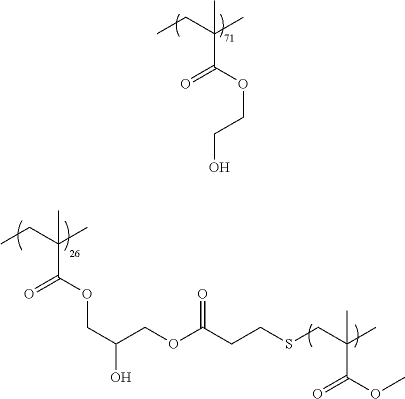

<<Preparation of Coating Composition>>

Single-wall CNTs (manufactured by KH Chemicals, HP, the average length of CNTs: 5 μm or longer) and the synthesized resin are added to o-dichlorobenzene (20 ml) and were adjusted so that the mass ratio of CNTs/the resin component reached 25/75.

This solution was mixed at 20° C. for 15 minutes using a mechanical homogenizer (manufactured by SMT Corporation, HIGH-FLEX HOMOGENIZER HF93), thereby obtaining a preliminary mixture.

The obtained preliminary mixture was dispersed in a constant-temperature layer (10° C.) at a circumferential velocity of 40 in/sec for five minutes using a thin film spin-type high-speed mixer “FILMIX 40-40 type” (manufactured by PRIMIX Corporation) and a high-speed spin thin film dispersion method, thereby preparing a coating composition which was used to form the thermoelectric conversion layer 14.

<<Measurement of Electrical Conductivity and Seebeck Coefficient>>

This coating composition was applied to a 25 μm-thick plastic film and was dried, thereby forming a 100 μm-thick thermoelectric conversion layer.

It was confirmed using a scanning electron microscope (SEM) that the lengths of the single-wall CNTs in the thermoelectric conversion layer sufficiently exceeded 1 μm.

The electrical conductivity (σ//) in the surface direction, the electrical conductivity (σ⊥) in the thickness direction, and the Seebeck coefficient S (a temperature difference ΔT=10 K) of the formed thermoelectric conversion layer were measured.

As a result, the electrical conductivity in the surface direction was 123 [S/cm], the electrical conductivity in the thickness direction was 11 [S/cm], and the Seebeck coefficient was 35 [μV/K].

<Production of Thermoelectric Conversion Element>

Two substrates (12A and 16A) having poorly thermal conductive portions (12a and 16a) made of polyimide and highly thermal conductive portions made of copper (12b and 16b), which are schematically illustrated in FIGS. 4A, 4C, and 4D, were prepared.

The thicknesses of the substrates were 50 μm, the thicknesses of the highly thermal conductive portions were 40 μm, and the widths of the poorly thermal conductive portion and the highly thermal conductive portion in the transverse direction on the surface on which the highly thermal conductive portion was exposed were 5 mm.

One of the substrates was used as the first substrate 12A, and the previously-prepared coating composition which was used to form the thermoelectric conversion layer was applied and dried on the surface on which the highly thermal conductive portion 12b was not exposed, thereby producing a total of 16 5 mm×5 mm thermoelectric conversion layers 14 having a thickness of 100 μm in a 4×4 form as schematically illustrated in FIGS. 4B and 4C. Meanwhile, the thermoelectric conversion layer 14 was formed so that the center thereof in the surface direction coincided with the boundary between the poorly thermal conductive portion 12a and the highly thermal conductive portion 12b.

The produced 16 thermoelectric conversion layers 14 in a 4×4 form were connected to each other in series using gold for the electrode 20 and the connection wire 26 as schematically illustrated in FIG. 4B.

Furthermore, the other substrate was used as the second substrate 16A, and the substrate was laminated with the surface thereof on which the highly thermal conductive portion 16b was not exposed facing the thermoelectric conversion layer 14 as schematically illustrated in FIG. 4A. The second substrate 16A was laminated so that the center of the thermoelectric conversion layer 14 in the surface direction coincided with the boundary between the poorly thermal conductive portion 16a and the highly thermal conductive portion 16b.

Therefore, a thermoelectric conversion module made up of the 16 thermoelectric conversion elements, which is schematically illustrated in FIGS. 4A to 4D, was produced.

### Comparative Example 1

A thermoelectric conversion module 50 was produced by using the same coating composition which was used to form the thermoelectric conversion layer and connecting 16 thermoelectric conversion elements (uni leg-type thermoelectric conversion elements), which are ordinary in the related art, illustrated in FIGS. 3A and 3B in series using a connection wire 60.

As a substrate 52, a 25 μm-thick polyimide film was used. For electrodes 54 and 58 and the connection wire 60, copper was used.

A thermoelectric conversion layer 56 was given a 5 mm×5 mm square article having a thickness of 100 μm.

[Evaluation]

For the thermoelectric conversion modules of Example 1 and Comparative Example 1 which were obtained as described above, the outputs were measured in a state in which a temperature difference of 10° C. was applied to the top and bottom of a sample.

As a result, the relative output of Example 1 was 11 when the output of the thermoelectric conversion module of Comparative Example 1 was standardized to 1.

### Example 2 and Comparative Example 2

Coating compositions which were used to form thermoelectric conversion layers were prepared in the same manner as in Example 1 except for the fact that the single-wall CNTs were changed to (CNTs manufactured by Meijo Nano Carbon, the average length of CNTs: 1 μm or longer).

100 μm-thick thermoelectric conversion layers were produced in the same manner as in Example 1 using the coating compositions. It was confirmed in the same manner as in Example 1 that the lengths of the single-wall CNTs in the thermoelectric conversion layer sufficiently exceeded 1 μm.

For the produced thermoelectric conversion layers, the electrical conductivities in the surface direction, the electrical conductivities in the thickness direction, and the Seebeck coefficients S were measured in the same manner as in Example 1.

As a result, the electrical conductivities in the surface direction were 1,990 [S/cm], the electrical conductivities in the thickness direction were 2 [S/cm], and the Seebeck coefficients were 56 [μV/K].

Thermoelectric conversion modules of Example 2 and Comparative Example 2, in which 16 thermoelectric conversion elements were connected to each other in series, were produced in the same manner as in Example 1 and Comparative Example 1 except for the fact that the above-described coating compositions were used, and the outputs thereof were measured.

As a result, the relative output of Example 2 was 995 when the output of the thermoelectric conversion module of Comparative Example 2 was standardized to 1.

### Example 3 and Comparative Example 3

Coating compositions which were used to form thermoelectric conversion layers were prepared by adding ethylene glycol (3% by mass) to a PEDOT.PSS solution (product name: Clevios PH 1000, manufactured by Heraeus Holding) obtained by dispersing PEDOT in poly(styrenesulfonate) (PSS).

50 nm-thick thermoelectric conversion layers were produced by applying and drying these coating compositions on 25 μm-thick plastic films.

For the produced thermoelectric conversion layers, the electrical conductivities in the surface direction, the electrical conductivities in the thickness direction, and the Seebeck coefficients S were measured in the same manner as in Example 1.

As a result, the electrical conductivities in the surface direction were 900 [S/cm], the electrical conductivities in the thickness direction were 2 [S/cm], and the Seebeck coefficients were 28 [μV/K].

Furthermore, thermoelectric conversion modules of Example 3 and Comparative Example 3, in which 16 thermoelectric conversion elements were connected to each other in series, were produced in the same manner as in Example 1 and Comparative Example 1 except for the fact that the above-described coating compositions were used, and the outputs thereof were measured.

As a result, the relative output of Example 3 was 450 when the output of the thermoelectric conversion module of Comparative Example 3 was standardized to 1.

### Example 4

An adhesive-free copper clad polyimide substrate (FELIOS R-F775, manufactured by Panasonic Corporation) was prepared. This copper clad polyimide substrate had a size of 80 mm×80 mm, the thickness of a polyimide layer was 20 μm, and the thickness of a copper layer was 70 μm.

The copper layer in the copper clad polyimide substrate was etched, thereby forming 1 mm-wide copper slide patterns at intervals of 1 mm. Therefore, a first substrate and a second substrate in which band-like highly thermal conductive portions having a thickness of 70 μm and a width of 1 mm were arranged at intervals of 1 mm in a direction orthogonal to the extension direction of the band on the surface of a 20 μm-thick sheet-like poorly thermal conductive portion.

A 150 nm-thick silicon oxide layer was formed as an adhesive layer on the entire surface (planar surface) of the first substrate which was fully a polyimide layer using an EB deposition method.

Next, 885 1 mm×1 mm patterns of the coating composition, which were the same as those in Example 1, were formed and dried on the adhesive layer at intervals of 1 mm in the extension direction of the band-like highly thermal conductive portion and at intervals of 1 mm in the arrangement direction of the band-like highly thermal conductive portions by means of screen printing. The formation and drying of the patterns were carried out three times, thereby producing 885 thermoelectric conversion layers having a thickness of 4.5 μm.

Meanwhile, the 1 mm×1 mm patterns were produced so that the centers thereof were located at the boundaries between the band-like highly thermal conductive portions and the band-like poorly thermal conductive portions.

Next, 1,000 nm-thick electrodes made of gold (Au) and connection wires were formed using a vacuum deposition method in which a metal mask was used, thereby connecting the 885 thermoelectric conversion layers in series as illustrated in FIG. 4B.

Next, a 150 nm-thick silicon oxide layer was formed as a gas barrier layer using an EB deposition method so as to fully cover the surface of the first substrate on which the thermoelectric conversion layer and the electrodes were formed.

Next, a 25 μm-thick piece of double-sided tape (manufactured by Nitto Denko Corporation, double-sided tape No. 5603) was glued onto the gas barrier layer as a gluing layer.

Furthermore, the second substrate was glued onto the gluing layer with the surface of the second substrate which was fully the poorly thermal conductive portion facing the gluing layer. Meanwhile, the second substrate was glued to the gluing layer so that the extension direction of the highly thermal conductive portions coincided with that in the first substrate, the end sides of the highly thermal conductive portions and the poorly thermal conductive portions were coincided with each other, and the highly thermal conductive portions and the poorly thermal conductive portions were located at positions different from those in the first substrate (refer to FIGS. 4A to 4C).

Therefore, a thermoelectric conversion module obtained by connecting 885 thermoelectric conversion elements having the same layer constitution as that of the thermoelectric conversion element illustrated in FIGS. 2A to 2C in series was produced.

### Example 5

The same first substrate and second substrate as in Example 4 were prepared.

A 100 nm-thick chromium (Cr) layer was formed as an adhesive layer on a surface of the first substrate which was fully a poorly thermal conductive portion using a vacuum deposition method in which a metal mask was used.

1,000 nm-thick electrodes made of gold (Au) and connection wires were formed on the chromium layer using a vacuum deposition method in which a metal mask was used so as to correspond to the same 885 thermoelectric conversion layers as in Example 4.

Next, 885 thermoelectric conversion layers were produced in the same manner as in Example 4.

Next, the double-sided tape as in Example 4 was glued as a gluing layer thereto so as to fully cover the surface of the first substrate on which the thermoelectric conversion layer and the electrodes were formed, and furthermore, a second substrate was glued thereto in the same manner as in Example 4.

Therefore, a thermoelectric conversion module obtained by connecting 885 thermoelectric conversion elements having the same layer constitution as that of the thermoelectric conversion element illustrated in FIGS. 2A to 2C except for the fact that the gas barrier layer 38 was not provided in series was produced.

### Example 6

A solution obtained by adding single-wall CNTs (CNTs manufactured by Meijo Nano Carbon, the average length of CNTs: 1 μm or longer) (50 mg) and a surfactant (manufactured by Wako Pure Chemical Industries, Ltd., sodium dodecylbenzenesulfonate, 150 mg) to ion-exchange water (20 ml) was prepared.

This solution was mixed at 20° C. for five minutes (18,000 rpm) using a mechanical homogenizer (manufactured by SMT Corporation, HIGH-FLEX HOMOGENIZER HF93), thereby obtaining a preliminary mixture.

The obtained preliminary mixture was dispersed at a circumferential velocity of 30 m/sec for five minutes using a thin film spin-type high-speed mixer “FILMIX 40-40 type” (manufactured by PRIMIX Corporation) and a high-speed spin thin film dispersion method while being cooled to 10° C., thereby preparing a coating composition which was used to form the thermoelectric conversion layer.

A 100 μm-thick thermoelectric conversion layer was produced in the same manner as in Example 1 using the coating composition. It was confirmed in the same manner as in Example 1 that the lengths of the single-wall CNTs in the thermoelectric conversion layer sufficiently exceeded 1 μm.

For the produced thermoelectric conversion layer, the electrical conductivity in the surface direction, the electrical conductivity in the thickness direction, and the Seebeck coefficient S were measured in the same manner as in Example 1.

As a result, the electrical conductivity in the surface direction were 450 [S/cm], the electrical conductivity in the thickness direction was 15 [S/cm], and the Seebeck coefficient was 52 [μV/K].

A thermoelectric conversion module was produced in the same manner as in Example 5 except for the fact that the above-described coating compositions were used and 885 thermoelectric conversion layers having a thickness of 8 μm were formed by means of a single round of screen printing.

Therefore, a thermoelectric conversion module obtained by connecting 885 thermoelectric conversion elements having the same layer constitution as that of the thermoelectric conversion element illustrated in FIGS. 2A to 2C except for the fact that the gas barrier layer 38 was not provided in series was produced.

### Example 7

A thermoelectric conversion module was produced in the same manner as in Example 6 except for the fact that, in a first substrate and a second substrate, the widths of band-like highly thermal conductive portions (the widths of copper strides) were set to 0.975 mm, the forming intervals between the band-like highly thermal conductive portions (the forming intervals between the copper strides) were set to 1.025 mm, and a gas barrier layer was formed in the same manner as in Example 4.

Meanwhile, in this thermoelectric conversion module, the second substrate was glued so that the end side opened a gap of 0.25 μm in an arrangement direction (that is, a conduction direction) of the highly thermal conductive portions without coinciding the end sides of the band-like highly thermal conductive portions in the first substrate and the second substrate with each other.

Therefore, a thermoelectric conversion module obtained by connecting 885 thermoelectric conversion elements having the same layer constitution as that of the thermoelectric conversion element illustrated in FIGS. 2A to 2C in series was produced.

### Example 8

A thermoelectric conversion module was produced in the same manner as in Example 1 except for the fact that, after the formation of a thermoelectric conversion layer, a 10 nm-thick buffer layer (manufactured by Kanto Kagaku, F4: TCNQ) was formed at an electrode connection portion of the thermoelectric conversion layer using a vacuum deposition in which a metal mask was used, and neither adhesive layer nor gas barrier layer were formed.

Therefore, a thermoelectric conversion module obtained by connecting 885 thermoelectric conversion elements having the same layer constitution as that of the thermoelectric conversion element illustrated in FIGS. 2A to 2C except for the fact that neither adhesive layer nor gas barrier layer were formed in series was produced.

[Evaluation]

On the thermoelectric conversion modules of Examples 4 to 8 which were produced as described above, the power generation amounts, bending tests, and heat resistance tests were carried out.

<Power Generation Amount>

The produced thermoelectric conversion module was sandwiched using a heated copper plate and a copper plate to which a coolant circulation device was connected, and the temperature of the heated copper plate was controlled so that the temperature difference between both copper plates reached 10° C.

Furthermore, the electrode for the thermoelectric conversion layer on the uppermost tier and the electrode for the thermoelectric conversion layer on the lowermost tier, which were connected to each other in series, were connected to a source meter (manufactured by Keithley Instruments, Inc., source meter 2450), the open voltage and the short-circuit current were measured, and the power generation amount was obtained from the following equation.

(Power generation amount)=0.25×(open voltage)×(short-circuit current)

<Bending Test>

After the measurement of the power generation amount, a bending test of the thermoelectric conversion module was carried out according to JIS K 5600. A cylindrical mandrel having a diameter of 32 mm was used, and the thermoelectric conversion module was bent at 180 degrees.

After the bending test, the power generation amount of the thermoelectric conversion module was measured in the same manner as described above, the change ratio between the power generation amounts was obtained, and the change ratio was determined according to the following evaluation standards.

A: The change ratio was 5% or lower

B: The change ratio was higher than 5% and 20% or lower

<Heat Resistance Test>

After the produced thermoelectric conversion module was left to stand in a constant-temperature tank at a temperature of 150° C. for 1,000 hours, the power generation amount was measured in the same manner as described above, the change ratio between the power generation amounts before and after the heating test was obtained, and the change ratio was determined according to the following evaluation standards.

A: The change ratio was 5% or lower

B: The change ratio was higher than 5% and 20% or lower

The results are shown in the following table.

TABLE 1

| | Layer constitution | | Evaluation | | |
|---|---|---|---|---|---|
| | | Gas | Power | | Heat |
| | Adhesive | barrier | generation | | resistance |
| | layer | layer | amount [μW] | Bending test | test |
| Example 4 | Yes | Yes | 1.1 | A | A |
| Example 5 | Yes | No | 1.0 | A | B |
| Example 6 | Yes | No | 1.9 | A | B |
| Example 7 | Yes | Yes | 2.2 | A | A |
| Example 8 | No | No | 1.3 | B | B |

The thermoelectric conversion layers in Examples 4, 5, and 8 included CNTs and a resin
The thermoelectric conversion layers in Examples 6 and 7 included CNTs and a surfactant

As shown the table, in Examples 4 to 7 in which the adhesive layer was provided, excellent results were obtained in the bending tests. In Examples 4 and 7 in which both the adhesive layer and the gas barrier layer were provided, excellent results were obtained in both the bending tests and the heat resistance tests.

In Examples 6 and 7 in which the thermoelectric conversion layers made up of CNTs and the surfactant were provided, the thermoelectric conversion modules had favorable power generation amounts, and, particularly, in Example 7 in which the highly thermal conductive portions were separated from each other in the conduction direction on the first substrate and the second substrate, a favorable power generation amount was obtained.

In Example 8 in which the thermoelectric conversion module had the buffer layer between the thermoelectric conversion layer and the electrodes, a more favorable power generation amount was obtained compared with that in Example 4 in which the same thermoelectric conversion layer was used.

Meanwhile, even when the thermoelectric conversion module is evaluated to be “B” in both the bending test and the heat resistance test, the thermoelectric conversion module is sufficiently available.

### Example 9

A thermoelectric conversion module produced using the same method as in Example 7 was adhered to a curved heating source having a diameter of 120 mm using a thermal conductive adhesive sheet (manufactured by Nitto Denko Corporation, TR5912F) at a surface temperature of 80° C.

Furthermore, a corrugated fin having a size of 80 mm×80 mm (manufactured by Saijo INX Co., Ltd., OA-5B2D75B) was adhered to the surface of the thermoelectric conversion module using the same thermal conductive adhesive sheet as described above.

The electrode for the thermoelectric conversion layer on the uppermost tier and the electrode for the thermoelectric conversion layer on the lowermost tier, which were connected to each other in series, were connected to a source meter (manufactured by Keithley Instruments, Inc., source meter 2450), the open voltage and the short-circuit current were measured, and the power generation amount was obtained. An output of 0.82 μW was obtained.

From this result, it was found that the thermoelectric conversion element of the present invention (the thermoelectric conversion module in which the thermoelectric conversion element of the present invention is used) is capable of generating electric power even when cooled in the air.

From the above-described results, the effects of the present invention are clear.

### EXPLANATION OF REFERENCES

10, 30: thermoelectric conversion element
12, 12A, 32: first substrate
12a, 16a, 30a, 42a: poorly thermal conductive portion
12b, 16b, 30b, 42b: highly thermal conductive portion
14, 36, 56: thermoelectric conversion layer
16, 16A, 42: second substrate
20, 24, 46, 48, 54, 58: electrode
26, 60: connection wire
34: adhesive layer
38: gas barrier layer
40: gluing layer
50: thermoelectric conversion module
52: substrate

What is claimed is:

1. A thermoelectric conversion element comprising:
a first substrate having a highly thermal conductive portion having a higher thermal conductivity than other regions in at least a part thereof in a surface direction;
a thermoelectric conversion layer which is formed on the first substrate, is made of an organic material, and has a higher electrical conductivity in the surface direction than in a thickness direction;
a second substrate which is formed on the thermoelectric conversion layer and has a highly thermal conductive portion which has a higher thermal conductivity than other regions in at least a part thereof in the surface direction and in which the highly thermal conductive portion does not fully overlap the highly thermal conductive portion of the first substrate in the surface direction; and
a pair of electrodes that are connected to the thermoelectric conversion layer so as to sandwich the thermoelectric conversion layer in the surface direction.

2. The thermoelectric conversion element according to claim 1,
wherein a ratio of the electrical conductivity in the surface direction to that in the thickness direction of the thermoelectric conversion layer is higher than 10 (the electrical conductivity in the surface direction:the electrical conductivity in the thickness direction>10:1).

3. The thermoelectric conversion element according to claim 2,
wherein the ratio of the electrical conductivity in the surface direction to that in the thickness direction of the thermoelectric conversion layer is higher than 100 (the electrical conductivity in the surface direction:the electrical conductivity in the thickness direction>100:1).

4. The thermoelectric conversion element according to claim 1,
wherein the thermoelectric conversion layer includes a carbon nanotube.

5. The thermoelectric conversion element according to claim 4,
wherein the thermoelectric conversion layer is formed by dispersing the carbon nanotube in a resin material.

6. The thermoelectric conversion element according to claim 4,
wherein the thermoelectric conversion layer contains the carbon nanotube and a surfactant.

7. The thermoelectric conversion element according to claim 4,
wherein the carbon nanotube is a single-wall carbon nanotube and has a length of 1 μm or longer.

8. The thermoelectric conversion element according to claim 1,
wherein the thermoelectric conversion layer includes a conductive polymer.

9. The thermoelectric conversion element according to claim 8,
wherein the conductive polymer is poly(3,4-ethylenedioxythiophene).

10. The thermoelectric conversion element according to claim 1,
wherein the highly thermal conductive portion in the first substrate and the highly thermal conductive portion in the second substrate are provided at different locations in a separation direction of the electrodes in the surface direction.

11. The thermoelectric conversion element according to claim 1,
wherein the highly thermal conductive portion in the first substrate and the highly thermal conductive portion in the second substrate are located on an external surface with respect to a lamination direction.

12. The thermoelectric conversion element according to claim 1,
wherein an adhesive layer is provided between the first substrate and the electrode pair.

13. The thermoelectric conversion element according to claim 1,
wherein a gas barrier layer covering the thermoelectric conversion layer and the electrode pair is provided.

14. The thermoelectric conversion element according to claim 1,
wherein an end surface of the thermoelectric conversion layer in the surface direction has a tapered shape.

15. The thermoelectric conversion element according to claim 1,
wherein each electrode of the electrode pair is formed so as to extend to a top surface from the end surface of the thermoelectric conversion layer in the surface direction.

16. The thermoelectric conversion element according to claim 1,
wherein a forming material of the electrode pair is gold and a buffer layer is provided between at least one electrode of the electrode pair and the thermoelectric conversion layer.

17. A method for manufacturing a thermoelectric conversion element comprising:
a step of treating a solution including at least a carbon nanotube and a dispersion medium using a high-speed spin thin film dispersion method and preparing a CNT coating fluid obtained by dispersing the carbon nanotube in the dispersion medium;
a step of applying and drying the CNT coating fluid on a first substrate having a highly thermal conductive portion having a higher thermal conductivity than other regions in at least a part thereof in a surface direction, thereby forming a thermoelectric conversion layer;
a step of connecting an electrode pair to the thermoelectric conversion layer so as to sandwich the thermoelectric conversion layer in the surface direction; and
a step of laminating a second substrate which has a highly thermal conductive portion having a higher thermal conductivity than other regions in at least a part thereof in the surface direction and in which the highly thermal conductive portion does not fully overlap the highly thermal conductive portion of the first substrate in the surface direction on the thermoelectric conversion layer.

18. The method for manufacturing a thermoelectric conversion element according to claim 17,
wherein the dispersion medium including the CNT coating fluid is a resin material.

19. The method for manufacturing a thermoelectric conversion element according to claim 17,
wherein the dispersion medium included in the CNT coating fluid is water and the CNT coating fluid contains a surfactant.

20. The method for manufacturing a thermoelectric conversion element according to claim 17,
wherein, in the step of forming the thermoelectric conversion layer, the CNT coating fluid is applied to the first substrate by means of printing.
